(19) United States
(12) Patent Application Publication
(10) Pub. No.: US 2026/0187313 A1
(43) Pub. Date: Jul. 2, 2026

(54) MACHINE LEARNING-BASED OPTIMIZATION OF PROCESSING SYSTEM HARDWARE

(71) Applicant: ADVANCED MICRO DEVICES, INC., Santa Clara, CA (US)

(72) Inventors: Aryaman Gadia, Hyderabad (IN); Sruthi Paturi, Hyderabad (IN); Sai Kumar Anisetti, Hyderabad (IN); Sujith Philip, Hyderabad (IN)

(21) Appl. No.: 19/004,900

(22) Filed: Dec. 30, 2024

(51) Int. Cl. G06F 30/27

(52) U.S. Cl. CPC G06F 30/27

(57) ABSTRACT

A processing system includes a plurality of hardware components and an intelligent optimization component. The intelligent optimization component includes at least one inference engine configured to receive a first input comprising a first encoded representation of at least a first hardware component of the plurality of hardware components and a second input including a second encoded representation of an application. Based on these inputs, the inference engine generates an output including at least one recommended hardware component upgrade for the processing system. The intelligent optimization component presents the at least one recommended hardware component upgrade to a user on a display coupled to the processing system.

### BACKGROUND

The evolution of computing system components, such as central processing units (CPUs), parallel processors (e.g., graphics processing units (GPUs)), displays, memory, storage devices, and the like, has been driven by an ever-increasing demand for high-performance computing and realistic graphical rendering. With each new generation, these components offer enhanced capabilities and improved efficiency, allowing for more complex and visually rich applications. However, these advancements have also increased the complexity of configuring and managing computing systems to achieve optimal performance.

While software and hardware improvements continually push the boundaries of what computing systems can achieve, users often retain their systems for several years, even as software requirements evolve. During this extended lifespan, users frequently encounter performance challenges due to shifts in application demands, hardware aging, and evolving system requirements. This variability can result in performance drops, inconsistent responsiveness, or inefficiencies, particularly when running newer, resource-intensive software on older hardware.

Additionally, even when upgrading individual components, such as the CPU or GPU, users may experience unexpected performance issues due to the complex interactions between system components. Factors such as power management, memory bandwidth, and display settings can all impact overall performance, leading to suboptimal experiences. These issues are further complicated by the diverse range of applications and workloads that modern systems must support, each with unique performance requirements.

### BRIEF DESCRIPTION OF THE DRAWINGS

The present disclosure may be better understood, and its numerous features and advantages made apparent to those skilled in the art by referencing the accompanying drawings. The use of the same reference symbols in different drawings indicates similar or identical items.

FIG. 1 is a block diagram of an example processing system, implementing an intelligent optimization component for analyzing performance, providing recommendations, and adjusting settings in real-time in accordance with some implementations.

FIG. 2 is a block diagram illustrating a more detailed view of the intelligent optimization component implemented by the processing system of FIG. 1 in accordance with some implementations.

FIG. 3 is a block diagram illustrating a more detailed view of a prediction unit of the intelligent optimization component in accordance with some implementations.

FIG. 4 is a diagram illustrating a machine learning (ML) module employing one or more machine learning networks for use by the intelligent optimization component in accordance with some implementations.

FIG. 5 is a block diagram lustrating an example of the intelligent optimization component operating in an upgrade analysis optimization mode in accordance with some implementations.

FIG. 6 is a block diagram lustrating an example of the intelligent optimization component operating in a system parameter tuning optimization mode in accordance with some implementations.

FIG. 7 is a block diagram lustrating an example of the intelligent optimization component operating in an application setting optimization mode in accordance with some implementations.

FIG. 8 is a flow diagram illustrating a method for training and utilizing one or more machine learning models to recommend hardware upgrades in an upgrade analysis optimization mode of the intelligent optimization component in accordance with some implementations.

FIG. 9 is a flow diagram illustrating a method for dynamically adjusting system parameters in a system parameter tuning optimization mode of the intelligent optimization component in accordance with some implementations.

FIG. 10 is a flow diagram illustrating a method for dynamically adjusting application-specific settings in an application setting optimization mode of the intelligent optimization component in accordance with some implementations.

### DETAILED DESCRIPTION

As modern computing systems continue to evolve, the increasing complexity of interactions between components such as CPUs, GPUs, neural processing unites (NPUs), memory, displays, and storage devices has created significant challenges for achieving optimal performance across various applications. Users often encounter difficulties when attempting to balance performance, power efficiency, and stability, particularly in resource-intensive scenarios like gaming, video editing, or scientific computing. These challenges are compounded by the fact that computing components, especially GPUs and CPUs, are typically retained for several years. During this time, software requirements and application technologies, such as gaming, advance rapidly, creating a gap between the capabilities of existing hardware and the demands of newer applications. As a result, even seemingly powerful systems can struggle to maintain consistent performance.

Issues arise when users attempt to upgrade individual components, such as replacing a GPU or adding more memory, only to find that the expected performance gains are not realized. This is often due to complex dependencies between system components, where one upgraded component may be bottlenecked by other, less powerful elements. For instance, a high-end GPU may not deliver its full potential if the CPU lacks the requisite processing power or if memory bandwidth is insufficient to support the increased data throughput. Similarly, power delivery and thermal management constraints can further limit system performance, causing instability or throttling even in otherwise well-configured systems. These dependencies are difficult for users to identify and resolve, often resulting in suboptimal performance and wasted investments in new hardware.

Another challenge stems from the need to optimize system parameters, such as clock frequency, voltage, and memory configurations, to achieve desired performance characteristics. Manually tuning these parameters is a complex and error-prone process that can lead to system instability or crashes, particularly when pushing hardware components to their limits. Users who lack deep technical expertise often resort to trial and error, risking hardware damage or rendering their systems unusable. Even automated tuning utilities provided by hardware manufacturers are limited in scope and lack the adaptability required to respond dynamically to varying workload demands.

Additionally, different applications, such as games, often have unique performance requirements and settings, such as frame rate scaling, latency reduction, and visual resolution enhancement. Optimizing game or other application settings, such as anti-aliasing, dynamic resolution scaling, or refresh rate synchronization is not straightforward, as incorrect configurations can lead to visual artifacts, input lag, or crashes that disrupt the user experience. As a result, users struggle to identify the ideal combination of settings that would maximize performance without compromising stability or visual quality.

As such, the techniques described herein provide for an intelligent optimization system that leverages machine learning to dynamically analyze and adjust both hardware and software based system configurations, real-time conditions, user preferences, a combination thereof, and the like. The system empowers users by recommending which components to upgrade based on their specific use cases and desired performance outcomes. For instance, in at least some implementations, the system analyzes current gameplay or other application characteristics and suggests upgrading the GPU, CPU, display, or another system component(s) to achieve a target frame rate or graphical quality. This targeted guidance helps users make informed decisions, avoiding unnecessary expenses and ensuring that each component is selected to complement the others.

Beyond upgrade recommendations, the system, in at least some implementations, also provides real-time tuning of system parameters, such as clock frequency, video random access memory (VRAM) frequency, voltage, and power, to achieve maximum frame rates and responsiveness during gameplay or other application usage. By continuously monitoring system stability and adjusting parameters within safe operating ranges, the system ensures that performance is optimized without causing crashes or overheating. This automated tuning process eliminates the need for manual intervention and allows the system to adapt to different workloads seamlessly.

Furthermore, in at least some implementations, the system intelligently configures game or other application settings to enhance the gaming (or other application) experience. For example, the system dynamically selects or fine-tunes settings, such as dynamic resolution scaling techniques to increase frame rates, anti-lag features to minimize input latency, and high-resolution rendering options to boost visual quality. Unlike traditional optimization approaches, which can result in instability or degraded performance when settings are misconfigured, the present techniques ensure that adjustments are made with a comprehensive understanding of the hardware and software environment. This minimizes the risk of crashes and ensures a smooth and immersive experience across diverse game or other application titles.

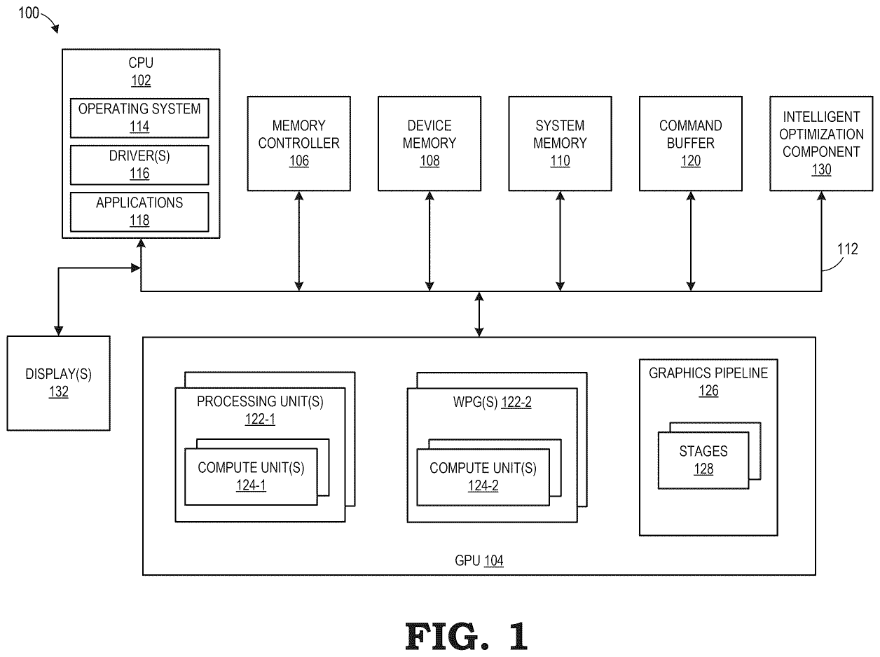

FIG. 1 is a block diagram illustrating a processing system 100, including an intelligent optimization component configured to dynamically analyze system performance, provide upgrade recommendations, and adjust system parameters and game (or other application) settings (e.g., settings controllable through a device driver) in real-time to optimize performance based on user preferences, application requirements, real-time conditions, a combination thereof, and the like. Although games are used as one illustrative example, the described techniques apply to various other types of applications as well. Also, the number and arrangement of components within the processing system 100 can differ across implementations, with some including more or fewer components than depicted in FIG. 1. Moreover, some implementations may feature additional components not illustrated in FIG. 1 or may organize the system differently. Components of the processing system 100 may be implemented using hardware, circuitry, firmware, software, or any combination of thereof.

In the depicted example, the processing system 100 includes a central processing unit (CPU) 102, an accelerated processor (AP) such as a graphics processing unit (GPU) 104, a memory controller 106, a device memory 108 utilized by the GPU 104, and a system memory 110 shared by the CPU 102 and the GPU 104. In at least some implementations, the CPU 102 and the GPU 104 are formed and combined on a single silicon die or package to provide a unified programming and execution environment. However, in other implementations, the CPU 102 and the GPU 104 are formed separately and mounted on the same or different substrates.

It should be understood that a GPU 104 is only one type of accelerated processor applicable to the techniques described herein. In other implementations, the AP includes any cooperating collection of hardware, software, or a combination thereof that performs functions and computations associated with accelerating graphics processing tasks, data-parallel tasks, nested data-parallel tasks in an accelerated manner with respect to resources, such as conventional CPUs, conventional GPUs, and combinations thereof. For example, in at least some implementations, an AP combines a general-purpose CPU and a graphics processing unit (GPU). In other implementations, the AP includes one or more parallel processors, such as vector processors, GPUs, general-purpose GPUs (GPGPUs), non-scalar processors, highly-parallel processors, artificial intelligence (AI) processors, inference engines, machine learning processors, neural processing units (NPUs), intelligence processing units (IPUs), and other multithreaded processing units). In at least some implementations, the AP is a dedicated GPU, one or more GPUs including several devices, or one or more GPUs integrated into a larger device. Additionally, the GPU 104, in at least some implementations, includes specialized processors such as digital signal processors (DSPs), field programmable gate arrays (FPGAs), and application-specific integrated circuits (ASICs), which can also be configured for parallel processing tasks.

The memory controller 106, in at least some implementations, includes any suitable hardware for interfacing with memories 108, 110. The memories 108, 110 include any of a variety of random access memories (RAMs) or combinations thereof, such as a double-data-rate dynamic random access memory (DDR DRAM), a graphics DDR DRAM (GDDR DRAM), and the like. The GPU 104 communicates with the CPU 102, the device memory 108, and the system memory 110 via a communications infrastructure 112, such as a bus. The communications infrastructure 112 interconnects the components of the processing system 100 and includes one or more of a peripheral component interconnect (PCI) bus, extended PCI (PCI-E) bus, advanced microcontroller bus architecture (AMBA) bus, advanced graphics port (AGP), or other such communication infrastructure and interconnects. In some implementations, communications infrastructure 112 also includes an Ethernet network or any other suitable physical communications infrastructure that satisfies an application's data transfer rate requirements.

As illustrated, the CPU 102 maintains, in memory, one or more control logic modules for execution by the CPU 102. The control logic modules, in at least some implementations, include an operating system (OS) 114, one or more drivers 116 (e.g., a user mode driver, a kernel mode driver, a graphics driver, etc.), and applications 118. These control logic modules control various features of the operation of the CPU 102 and the GPU 104. For example, the operating system 114 directly communicates with hardware and provides an interface to the hardware for other software executing on the CPU 102. The driver(s) 116, including the graphics driver, controls the operation of the GPU 104 by, for example, providing an application programming interface (API) to software (e.g., applications 118) executing on the CPU 102 to access various functionality of the GPU 104. For example, in at least some implementations, an application 118 utilizes a graphics API to invoke a driver 116, such as a graphics driver. The driver 116 issues one or more commands to the GPU 104 for rendering one or more graphics primitives into displayable graphics images. Based on the graphics instructions issued by the application 118 to the driver 116, the driver 116 formulates one or more graphics commands that specify one or more operations for the GPU 104 to perform for rendering graphics. In at least some implementations, the driver 116 is a part of the application 118 running on the CPU 102. In one example, the driver 116 is part of a gaming application running on the CPU 102. In another example, the driver 116 is part of the operation system 114 running on the CPU 102. The graphics commands generated by the driver 116 include graphics commands intended to generate an image or a frame for display. The driver 116 translates standard code received from the API into a native format of instructions understood by the GPU 104. Graphics commands generated by the driver 116 are sent to the GPU 104 for execution. The GPU 104 executes the graphics commands and uses the results to control what is displayed on a display screen.

In at least some implementations, the CPU 102 sends graphics commands, compute commands, or a combination thereof intended for the GPU 104 to a command buffer 120. Although depicted in FIG. 1 as a separate component for ease of illustration, the command buffer 120, in at least some implementations, is located in device memory 108, system memory 110, or a separate memory coupled to the communication infrastructure 112. The command buffer 120 temporarily stores a stream of graphics commands that include input to the GPU 104. The stream of graphics commands includes, for example, one or more command packets and/or one or more state update packets.

The GPU 104, in at least some implementations, accepts both compute commands and graphics rendering commands from the CPU 102 or another processor. In at least some implementations, the GPU 104 executes commands and programs for selected functions, such as graphics operations and other operations that are particularly suited for parallel processing. In general, the GPU 104 is frequently used for executing graphics pipeline operations, such as pixel operations, geometric computations, and rendering an image to a display. In some implementations, the GPU 104 also executes compute processing operations (e.g., those operations unrelated to graphics such as video operations, physics simulations, computational fluid dynamics, etc.), based on commands or instructions received from the CPU 102. For example, such commands include special instructions that are not typically defined in the instruction set architecture (ISA) of the GPU 104. In some implementations, the GPU 104 receives an image geometry representing a graphics image, along with one or more commands or instructions for rendering and displaying the image. In various implementations, the image geometry corresponds to a representation of a two-dimensional (2D) or three-dimensional (3D) computerized graphics image.

In various implementations, the GPU 104 includes one or more processing units 122 (illustrated as processing unit 122-1 and processing unit 122-2). One example of a processing unit 122 is a workgroup processor (WGP) 122-2. In at least some implementations, a WGP 122-2 is part of a shader engine (not shown) of the GPU 104. Each of the processing units 122 includes one or more compute units 124 (illustrated as compute unit 124-1 and compute unit 124-2), such as one or more stream processors (also referred to as arithmetic-logic units (ALUs) or shader cores), one or more single-instruction multiple-data (SIMD) units, one or more logical units, one or more scalar floating point units, one or more vector floating point units, one or more special-purpose processing units (e.g., inverse-square root units, since/cosine units, etc.), a combination thereof, or the like. Stream processors are the individual processing elements that execute shader or compute operations. Multiple stream processors are grouped together to form a computer unit or a SIMD unit. SIMD units, in at least some implementations, are each configured to execute a thread concurrently with execution of other threads in a wavefront (e.g., a collection of threads that are executed in parallel) by other SIMD units, e.g., according to a SIMD execution model. The SIMD execution model is one in which multiple processing elements share a single program control flow unit and program counter and thus execute the same program but are able to execute that program with different data. The number of processing units 122 implemented in the GPU 104 is configurable. Each processing unit 122 includes one or more processing elements such as scalar and or vector floating-point units, arithmetic logic units (ALUs), and the like. In various implementations, the processing units 122 also include special-purpose processing units (not shown), such as inverse-square root units and sine/cosine units.

Each of the one or more processing units 122 executes a respective instantiation of a particular work item to process incoming data, where the basic unit of execution in the one or more processing units 122 is a work item (e.g., a thread). Each work item represents a single instantiation of, for example, a collection of parallel executions of a kernel invoked on a device by a command that is to be executed in parallel. A work item executes at one or more processing elements as part of a workgroup executing at a processing unit 122.

The GPU 104 issues and executes work-items, such as groups of threads executed simultaneously as a “wavefront”, on a single SIMD unit. Wavefronts, in at least some implementations, are interchangeably referred to as warps, vectors, or threads. In some implementations, wavefronts include instances of parallel execution of a shader program, where each wavefront includes multiple work items that execute simultaneously on a single SIMD unit in line with the SIMD paradigm (e.g., one instruction control unit executing the same stream of instructions with multiple data).

The parallelism afforded by the one or more processing units 122 is suitable for graphics-related operations such as pixel value calculations, vertex transformations, tessellation, geometry shading operations, and other graphics operations. A graphics processing pipeline 126 accepts graphics processing commands from the CPU 102 and thus provides computation tasks to the one or more processing units 122 for execution in parallel. In at least some implementations, the graphics pipeline 126 includes a number of stages 128, each configured to execute various aspects of a graphics command. Some graphics pipeline operations, such as pixel processing and other parallel computation operations, require that the same command stream or compute kernel be performed on streams or collections of input data elements. Respective instantiations of the same compute kernel are executed concurrently on multiple compute units 124 in the one or more processing units 122 to process such data elements in parallel. As referred to herein, for example, a compute kernel is a function containing instructions declared in a program and executed on a processing unit 122 of the GPU 104. This function is also referred to as a kernel, a shader, a shader program, or a program.

One or more display devices 132 (also referred to herein as a “display 132”) are coupled to the processing system 100. The display(s) 132 provides a visual interface for rendering and presenting the output of graphics or other processing tasks performed by, for example, the CPU 102 and the GPU 104. In at least some implementations, the display(s) 132 includes a monitor(s), a television(s), a projector(s), a virtual reality headset(s), augmented reality glasses, or other types of visual output devices. The GPU 104 communicates with the display devices 132 through one or more interfaces, such as High-Definition Multimedia Interface (HDMI), DisplayPort, or similar connections, and manages the rendering pipeline to ensure that processed graphics data is displayed in real time, adhering to user-defined or application-specific visual quality and performance goals.

FIG. 1 further shows that the processing system includes an intelligent optimization component (IOC) 130. The IOC 130 is configured to dynamically monitor performance of the processing system 100 an applications 118, recommend upgrades, and adjust parameters and settings of the processing system 100 or applications 118 in real-time to optimize overall performance based on application requirements and user preferences. In at least some implementations, the IOC 130 is implemented using one or more hardware components, circuitry, firmware, a firmware-controlled microcontroller, or a combination thereof. Although illustrated as a separate component, the IOC 130, in other implementations, is implemented within the CPU 102, the GPU 104, or another component, or is distributed across multiple components within the processing system 100. For example, the IOC 130 may be implemented as one or both of the CPU 102 or GPU 104 executing software composed of executable instructions that, when executed, manipulate the CPU 102 and/or the GPU 104 to perform actions ascribed to the IOC 130 in the following description. In some implementations, the IOC 130 may also be implemented on a remote server or cloud system.

As described in greater detail below, by leveraging machine learning techniques, the IOC 130 analyzes system conditions, including resource utilization, power states, and temperature thresholds, to make informed adjustments to parameters such as clock frequencies, voltage levels, and memory configurations. The IOC 130 also facilitates seamless performance management by providing targeted recommendations for upgrading specific system components (e.g., GPU, CPU, display, memory, etc.) to meet desired performance characteristics, such as achieving higher frame rates or reducing latency for gaming or compute-intensive applications. Additionally, the IOC 130 automatically fine-tunes game-specific settings (controllable through a device driver), such as resolution scaling, anti-lag, and visual quality enhancements, ensuring that performance improvements are achieved without compromising system stability or causing application crashes. Through this integrated optimization approach, the IOC 130 enhances the overall user experience and maximizes the efficiency of the processing system 100.

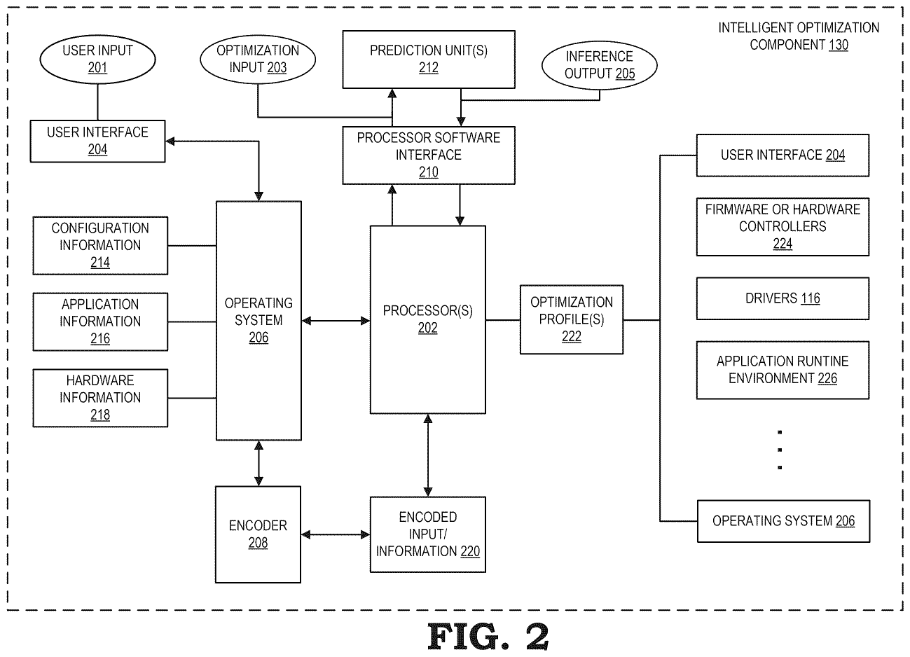

FIG. 2 is a block diagram illustrating one example of a high-level overview of the IOC 130. In this example, the IOC 130 includes at least one processor 202 (e.g., one or more of the CPU 102 or GPU 104 of FIG. 1, accelerated processors, or any other processing or coprocessing units), a user interface 204, an operating system 206 (e.g., the OS 114 of FIG. 1), a data encoder 208, a processor software interface 210, and one or more prediction units 212. One or more of these components of the IOC are implemented as hardware, separate fixed-function circuitry, firmware, a firmware-controlled microcontroller, software operating on the processor 202 or another processor, or any combination thereof.

The encoder 208, in at least some implementations, is part of prediction unit 212. In other implementations, the encoder 208 is separate from the prediction unit 212. In at least some implementations, the user interface 204 is a graphical or non-graphical user interface presented to the user of the processing device 100 that allows the user to interact with the IOC 130. The user interface 204 presents various configuration options and performance data, enabling the user to view, select, and fine-tune optimization parameters according to specific use cases or preferences. The user provides input 301 through the user interface 204 to enable, disable, or customize the optimization processes carried out by the IOC 130.

For example, in at least some implementations, the user provides user input 201 that specifies one or more optimization modes for performance and configuration optimization. In at least some implementations, these modes include an upgrade analysis and recommendation mode, a system parameter tuning mode, an application setting optimization mode, and the like. Depending on the selected mode, the IOC 130 dynamically adjusts system parameters or provides upgrade recommendations. The upgrade analysis and recommendation mode analyzes the current system configuration and suggests potential hardware upgrades (e.g., CPU, GPU, etc.) to achieve a desired performance target, such as higher FPS or reduced latency. The system parameter tuning mode focuses on fine-tuning low-level parameters like clock frequency, voltage, and power consumption to optimize one or more metrics, such as frames per second (FPS), system stability, and the like. The application setting optimization mode automatically configures game settings (e.g., resolution, anti-lag, frame rate scaling, etc.) for enhanced gameplay performance without causing instability.

In at least some implementations, the user also provides input 201 specifying the performance metrics they aim to improve. These metrics include, for example, FPS, resolution, video quality, input lag, CPU/GPU utilization, and the like. Based on the selected metrics, the IOC 130 adjusts its tuning/optimization strategy to prioritize the desired outcomes. For example, if the user specifies FPS as a priority, the IOC 130 increases GPU clock speeds and adjusts VRAM frequency, whereas if reducing input lag is prioritized, the IOC 130 enables anti-lag features and adjusts power delivery to achieve faster response times. This user-defined input ensures that the IOC 130 focuses on optimizing the metrics most relevant to the user's experience.

The user, in at least some implementations, is able to further refine the optimization by selecting specific games or applications that they want to optimize. This input allows the IOC 130 to create game-specific profiles, tuning both hardware and application settings based on the unique characteristics of each game or application. For instance, a user may select “Game A” to optimize for maximum FPS and “Game B” to optimize for reduced input lag. The IOC 130 stores these game-specific profiles and automatically applies them when the corresponding game or a similar game is launched. Alternatively, if the user does not specify a particular game, the IOC 130, in at least some implementations, applies general optimization settings based on the selected optimization mode and performance metrics.

In at least some implementations, the user interface 204 also provides feedback on the applied optimizations, displaying real-time performance metrics such as current FPS, CPU/GPU usage, power consumption, and overall system stability. This feedback enables the user to assess the effectiveness of the selected optimizations and make adjustments if needed. By providing the user with options to select optimization modes, specify performance metrics, and choose game-specific profiles, the IOC 130 delivers a highly customizable and user-centric approach to system performance management, ensuring that the system resources are utilized effectively to meet the user's specific gameplay and application requirements.

In at least some implementations, the OS 206 (or another component) obtains input, such as optimization input 203, to be used by the IOC 130 as part of the data set that one or more of the selected optimization modes work on to generate their respective outputs. The optimization input 203, in at least some implementations, includes data that varies based on the type of optimization being performed and the user-defined objectives for enhancing system performance. Examples of the optimization input 203 include one or more of configuration information 214, application information 216, hardware configuration information 218, and the like. In at least some implementations, the optimization input 203 also includes the user input 201. The configuration information 214 includes, for example, real-time system configuration data, such as the current (or base) clock frequency, VRAM frequency, voltage, power consumption, temperature, and other tunable system parameters of the CPU 102 and the GPU 104. In at least some implementations, the configuration information 214 also includes power states, memory usage, and system thermal limits, which are used to analyze and refine system parameters in real-time based on the selected optimization mode.

The application information 216 includes, for example, data specific to the applications or games targeted for optimization, such as application titles, application genres, or application tunable parameters. For instance, the application information 216, in at least some implementations, identifies whether the application is a graphics-intensive game, a simulation, a video processing application, or the like. In at least some implementations, the application information 216 indicates specific game genres (e.g., action, role-playing game (RGP), simulation, etc.), settings (e.g., anti-aliasing level, texture quality, frame rate targets, etc.), and the like, or other application categories, such as simulators and modeling applications. This data enables the selected optimization mode to fine-tune performance settings based on the characteristics and requirements of each application. Additionally, the application information 216, in at least some implementations, includes user-specified preferences for particular applications or general application categories, which guide the optimization modes in determining how to adjust settings.

The hardware configuration information 218 includes, for example, details on the hardware components within the processing system 100. In at least some implementations, this information includes one or more of CPU and GPU type, model information, core count, thread count, base clock speed, boost clock speed, thermal design power (TDP), cache size, memory configuration, ray-tracing capability, other specifications, and the like. For display devices, the hardware configuration information 218 includes, for example, information such as display type, refresh rate, resolution (e.g., 1080p, 1440p, 4K), supported color gamut, display size, and the like. This information is used by one or more of the optimization modes to assess current hardware limitations, adjust system parameters, recommend specific configurations or upgrades, and the like based on the user's defined performance metrics and system goals.

In at least some implementations, the IOC 130 operates on an encoded representation of one or more different types of the optimization input 203 (e.g., the application information 216 and the hardware configuration information 218) to enable efficient comparison and reuse of optimization processes for similar components. The encoding is performed by an encoder 208 that generates or outputs encoded optimization information 220 (also referred to herein as “encoded information 220”), which represents the optimization input 203 as numerical vectors, each capturing the unique characteristics of one or more of the components, applications, and configuration parameters of the processing system 100. This encoded information 220 is used by the IOC 130 to allow similar components or applications to be represented using matching or similar encodings, ensuring that optimization processes trained on one set of components can be reused for other sets of components having similar encodings. For example, a game with an “Action” and “Multiplayer” classification is encoded similarly to other games sharing those attributes, enabling optimizations tuned for that genre to be utilized across a wider set of games.

The encoder 208, in at least some implementations, obtains one or more types of optimization input 203 (e.g., the application information 216 and the hardware configuration information 218) from the OS 206, directly from memory (e.g., system memory 110), or another component and generates the corresponding encoded information 220. Each type of input is processed differently to create encoding vectors that capture one or more features, attributes, or the like relevant to optimization. For example, the application information 216, such as the game's genre, is encoded into an N-bit vector (e.g., a 12-bit vector) where each bit represents a particular game genre or attribute. The bits hold values for genres such as Action, RPG, Strategy, Combat, Adventure, Open World, Fantasy, Racing, Massively Multiplayer, Simulation, Indie and Sports, and the like. For example, consider a game “Game A” for which the encoder 208 generates a vector [1,0,0,1,0,0,0,0,1,0,0,0]. This encoding indicates the game's classification as an action, combat, and massively multiplayer game. The overlap between genres ensures that optimization models implemented by the prediction unit 212 and trained on one set of games can also be applied to other games with similar features, leveraging prior training data. In at least some implementations, the encoder 208 performs one or more feature extraction operations to identify or obtain the attributes of a hardware component or an application for encoding.

Similarly, the hardware configuration information 218 is encoded into a numerical vector that captures one or more attributes of hardware components of the processing system 100, such as CPU, GPU, display, motherboard, and the like. For instance, a CPU descriptor vector, in at least some implementations, includes values for core count, thread count, architecture type, base clock speed, boost clock speed, cache sizes (e.g., L1 cache, L2 cache, L3 cache, etc.), thermal design power (TDP), motherboard overclocking tolerance (MOT), and the like. In an example, “CPU A” has an encoded vector of [6, 12, 3, 3.7, 4.6, 0, 3, 32, 65, 95], where the values represent the number of cores, number of threads, architecture label (e.g., “zen3” encoded as a numerical value), base clock speed in GHz, boost clock speed in GHz, and various cache sizes in megabytes (MB). For GPUs, the encoded vector, in at least some implementations, includes attributes such as compute units, game clock, boost clock, memory, ray tracing support, high-speed GPU cache, power consumption, power supply requirements, and the like. In an example, “GPU A” is represented with an encoding of [16, 2.65, 2.815, 4, 1, 16, 107, 400], where the numerical values correspond to the compute units, game clock, boost clock, memory size in GB, ray tracing capability (1 indicating presence), high-speed GPU cache size, power in watts, and minimum PSU requirements. The resulting numerical vector is output as part of the encoded information 220.

The display configuration, in at least some implementations, is represented using a 1-bit value that indicates the resolution used for optimization. The encoding values, in at least some implementations, are (0) for 1080p displays, (1) for 1440p displays, and (2) for 2160p (4K) displays. This simplified encoding allows the IOC 130 to match optimization profiles to appropriate display configurations quickly. The encoded display configuration is output as part of the encoded information 220.

In at least some implementations, the configuration information 214 related to tunable system parameters (e.g., current CPU and GPU clock frequencies, VRAM frequency, voltage, power states, etc.) is also converted into an encoded format and output as part of the encoded information 220. This ensures that the IOC 130 is able to compare these values against target configurations and identify ranges that maximize performance or efficiency. For example, a GPU configuration with a clock frequency of 2.65 GHz, VRAM frequency of 4 GHz, and power consumption of 107 W is encoded as [2.65, 4, 107]. This encoding allows the IOC 130 to quickly identify similar configurations and apply pre-learned adjustments. In other implementations, the configuration information 214 is not converted in an encoded format.

In at least some implementations, the encoder 208 combines the different encoded representations into a unified composite vector, which is then included in the encoded information 220 and used by the various optimization modes. This composite vector, in at least some implementations, includes concatenated sub-vectors representing on or more of application details, hardware capabilities, and current configuration settings, providing a holistic view of the system state and optimization objectives. For example, an optimization mode targeting FPS enhancement for a specific game may receive a composite vector that combines the game's genre encoding, GPU configuration, and display resolution, enabling the mode to analyze how adjusting system parameters (e.g., clock speed) would impact FPS for that particular game. In at least some implementations, the optimization input 203 is or at least includes the encoded information 220 along with any relevant user input 201.

By operating on the encoded representations of the optimization input 203, the IOC 130 is able to efficiently compare different configurations and generate tailored outputs. The use of a standardized encoding scheme allows the optimization modes to apply similar optimization strategies across various games, applications, and hardware configurations. For example, if a specific tuning profile is found to improve FPS in one action game, this profile can be recommended for use in other action games sharing a similar encoding, thus reducing the need to develop unique profiles for each game. The encoding also facilitates the use of distance metrics, such as cosine similarity, to group similar components together and identify the optimal configuration for any given set of encoded inputs. This enables a scalable and flexible framework for real-time system optimization across diverse computing environments.

The processor software interface 210, in at least some implementations, refers to drivers, such as kernel mode, user mode, and firmware components, as well as software development kit (SDK) libraries. The processor software interface 210 collects or obtains any unencoded optimization input 203 (e.g., configuration information 214, application information 216, hardware configuration information 218, etc.) from the OS 206 or other components and encoded optimization information 220 from the encoder 208. The processor software interface 210 passes the encoded information 220 and any additional optimization input 203 to the prediction unit 212 and receives the resulting inference output, such as one or more optimization profiles 222, generated by the prediction unit 212. The unencoded optimization input 203, in at least some implementations, includes real-time performance metrics, hardware configurations, and user preferences, while the encoded information 220 provides standardized representations of similar components and applications, allowing for efficient analysis by the prediction unit 212.

The prediction unit 212 is a data-driven optimization unit that utilizes artificial intelligence to perform machine learning tasks and analytical processes to generate an inference output 205 that includes one or more optimization profiles 222 based on the selected optimization mode(s) (e.g., upgrade recommendations, system parameter tuning, application-specific settings, etc.) and the collected inputs. The prediction unit 212 receives the encoded information 220 and any additional optimization inputs 203 from the processor software interface 210 and, in at least some implementations, also receives user-specified inputs, such as target performance metrics (e.g., FPS, resolution, latency, etc.) or specific applications to be optimized. The inference output 205 generated by the prediction unit 212 includes one or more optimization profiles 222 that specify recommended changes or configurations tailored to the active optimization mode(s). For example, the inference output 205, in at least some implementations, includes one or more of upgrade recommendations (e.g., suggesting a higher-end GPU or CPU based on detected performance bottlenecks), real-time system parameter tuning (e.g., adjusting clock frequencies, voltages, power states, etc.), or optimized application settings (e.g., adjusting resolution, frame rate, or other graphics settings) for the processing system 100.

The inference output 205 is then passed to the processor software interface 210, where the inference output 205, such as the optimization profiles 222, is provided to, applied to, or utilized by various system components, such as the user interface 204, firmware or hardware controllers 224, drivers 116, application runtime environment 226, the operating system 206, and the like to implement the optimizations defined by the selected optimization mode(s). Each component leverages the optimization profiles 222 differently based on the type of optimization being performed. For example, the user interface 204, in at least some implementations, displays upgrade recommendations or performance metrics to the user, allowing the user to review, accept, or modify the suggested optimizations. When an upgrade analysis optimization mode is active, the user interface 204 presents upgrade recommendations, such as suggestions to replace the CPU 102 or the GPU 104 based on detected performance bottlenecks.

The firmware or hardware controllers 224 (e.g., voltage regulators, power management units, Basic Input/Output System (BIOS) firmware, Unified Extensible Firmware Interface (UEFI) firmware, etc.) receive the optimization profiles 222 as part of the system parameter tuning optimization mode. In at least some implementations, the profiles 222 generated for this optimization mode include, for example, real-time adjustments to clock frequencies, voltages, or power states to maximize performance while maintaining system stability. For example, if the optimization profile 222 specifies a change in the GPU clock speed, the firmware or hardware controllers 224 execute this change to meet the desired FPS or thermal targets (e.g., a decrease in thermal output, a specified thermal output or output range, and the like).

Drivers 116 (e.g., GPU, CPU, or system management drivers), in at least some implementations, also receive one or more optimization profiles 222 depending on the active optimization mode. For instance, when the application setting optimization mode is active, drivers 116, such as graphics drivers, receive settings for resolution scaling, anti-aliasing, refresh rate adjustments, and the like. These drivers 116 then apply the settings at the hardware level to ensure that the application or game operates under the optimized configuration, providing a balance between performance and visual quality.

The application runtime environment 226, in at least some implementations, is used to directly implement optimizations that affect the active application's settings. For example, when the optimization profile targets a specific game, the runtime environment 226 adjusts internal game settings, such as texture quality, frame rate limits, or input lag parameters. The application runtime environment 226 uses these settings to achieve the target performance metrics (e.g., high FPS or low latency) defined by the optimization profile 222.

In at least some implementations, the operating system 206 utilizes one or more optimization profiles 222 to make system-level adjustments, such as modifying power plans, adjusting global resolution settings, or configuring CPU and GPU resource allocation. For instance, if an optimization profile 222 specifies a high-performance mode, the operating system 206 changes system power settings to prioritize performance over power efficiency.

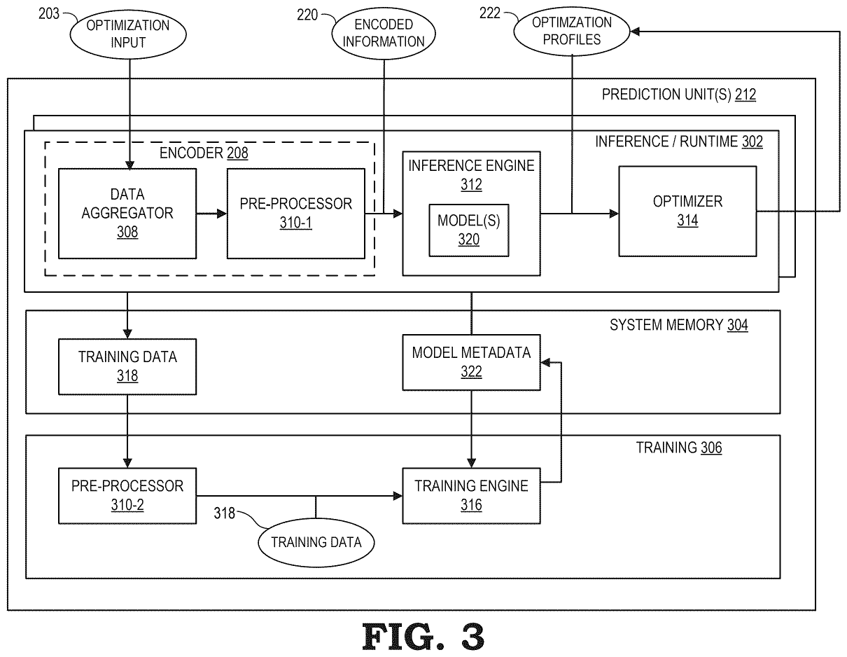

The IOC 130, in at least some implementations, performs one or more of the processes described herein (obtaining the optimization input 203, encoding the input to generate the encoded information 220, training one or more models 320 (FIG. 3) using the encoded information 220, using the models 320 to generate optimization profiles 222, and the like) in response to receiving a request from a user to perform optimization or in response to detecting one or more specified events. For example, if the IOC 130 detects an event (e.g., launching a new game, switching to a high-resolution display, or a change in system configuration), the IOC 130 dynamically reconfigures one or more system parameters or application settings based on the selected optimization mode to ensure that the processing device 100 operates according to the user's defined performance goals or application-specific requirements. In at least some implementations, the IOC 130 dynamically transitions between different optimization modes as the context of the active application changes. For instance, if a game switches from a graphically intense cutscene to standard gameplay, the component may switch from a high-quality mode to a high-FPS mode by adjusting clock frequencies, resolution, or visual quality settings in real-time. Such adaptive optimizations allow the system to respond to varying workload demands, achieving an optimal balance between performance and efficiency without user intervention.

FIG. 3 illustrates a more detailed view of the prediction unit 212 in the IOC 130. In the example shown in FIG. 3, the prediction unit 212 includes one or more inference/runtime pipelines 302, at least a portion 304 of the system memory 110, and one or more training pipelines 306. In the example shown in FIG. 3, the inference/runtime pipeline 302 includes the encoder 208, an inference engine 312, and an optimizer 314. The training pipeline 306, in at least some implementations, includes a training engine 316, and an optimizer 314. It is noted that the prediction unit 212, in at least some implementations, includes other components not shown in FIG. 3 or includes components different from those shown in FIG. 3.

The encoder 208 operates as described above with respect to FIG. 2 to collect, aggregate, and encode the relevant optimization inputs 203, such as user input 201, configuration information 214, application information 216, and hardware configuration information 218. In the example shown in FIG. 3, the encoder 208 includes a data aggregator 308 and pre-processor 310-1. The data aggregator 308 collects and aggregates the raw optimization input 203 from various sources (e.g., system logs, user inputs, and performance metrics, etc.) received through the processor software interface 210. In at least some implementations, a copy of the optimization input 203 (including user input 201) is stored in a portion 304 of the system memory 110 as training data 318.

The aggregated data is then passed to the pre-processor 310-1, which performs operations such as encoding categorical data into vector formats, normalizing numerical values, and organizing the inputs into a structured format for machine learning models. For example, games/applications are encoded into an N-bit vector representation, where N is specific to the features of the game or application (e.g., genre, resolution, priority) being encoded, while hardware components (e.g., CPU, GPU, etc.) are encoded into different N-bit vectors that describe their respective specifications and features (e.g., cores, clock speed, memory configuration, etc.), with N varying based on the number of attributes and features being encoded. The output of the pre-processor 310-1, in at least some implementations, is the encoded information 220 described above with respect to FIG. 2. In at least some implementations, a copy of the encoded information 220 is stored in a portion 304 of the system memory 110 as training data 318.

The inference engine 312, in at least some implementations, is an artificial intelligence engine that implements one or more machine learning-based models 320. As described below, the machine learning (ML) model(s) 320 is trained to generate one or more optimization profiles 222 that are tailored to the processing device 100 based on a selected optimization mode(s) (e.g., upgrade recommendations, system parameter tuning, application-specific settings, etc.). In at least some implementations, the inference engine 312 implements a single model 320 for all optimization modes. In other implementations, the inference engine 312 implements one or more separate models 320 for each optimization mode or a combination of optimization modes. The inference engine 312, in at least some implementations, is implemented using one or more hardware components, circuitry, firmware, a firmware-controlled microcontroller, or a combination thereof.

The inference engine 312, in at least some implementations, takes as input one or more of the user input 201, optimization input 203, or the encoded information 220. In at least some implementations, the inference engine 312 also takes model metadata 322 as input. The model metadata 322 includes a model architecture(s), learned weights, any runtime settings, and the like for one or more machine learning models 320 implemented by the inference engine 312. The model metadata 322 includes information used by the inference engine 312 for both local function fitting (e.g., fine-tuning a neural network) and local inference.

Additionally, different optimization tasks may utilize different hardware features of the processing system 100. For instance, in at least some implementations, the upgrade analysis optimization mode utilizes, for example, CPU resources during inference, relying on cores, one or more control units, one or more ALUs, and one or more registers to handle computations without significant GPU or AP involvement. The system and/or parameter tuning optimization modes, in at least some implementations, utilizes, for example, GPU or AP hardware components, including compute units, memory units (e.g., VRAM), voltage regulator modules (VRMs), and unified shader architecture for running one or more models. Other hardware features, such as the cooling system and multi-level parallelism capabilities, may also be utilized depending on specific tuning scenarios and workload demands. In at least some implementations, the application setting optimization mode uses, for example,

In at least some implementations, the model metadata 322 is generated or refined based on a training process performed by the training engine 316. For example, the training engine 316 takes as input the training data 318 stored in a portion 304 of the system memory 110. It should be understood that although FIG. 3 shows the training data 318 as being stored in a portion 304 of the system memory 110, in other implementations, at least a portion of the training data 318 is stored in another location on the processing system 100, in a location remote from the processing system 100, or a combination thereof.

The training data 318, in at least some implementations, includes one or more different types of training data, such as configuration information, application information, hardware information, user-defined goals or performance targets (e.g., achieving a specific FPS or reducing input latency for a given application), encoded information, and the like. In at least some implementations, the user-defined goals or performance targets are used to further tailor the ML models 320 to prioritize specific outcomes during training based on user preferences. Additionally, in at least some implementations, the training data 318 is generated specifically for training, is a copy of at least one of the user inputs 201, optimization inputs 203, or encoded information 220 received from the processor software interface 210 over time, a combination thereof, or the like. Similar to the inference/runtime pipeline 302, the training pipeline 306, in at least some implementations, includes a pre-processor 310-2 to perform the encoding functions described above on raw training data if needed.

As described above, encoded information includes vector representations for various components (e.g., games, applications, CPUs, GPUs, displays, etc.), which are used to facilitate consistency and efficiency during model training and inference. For example, when encoded information is provided as part of the training data 318, this information includes multiple encodings for various attributes, such as a game title, a GPU, a CPU, a display resolution, a performance metric (e.g., FPS), and the like obtained for the game given the specific hardware and software configuration represented by the encoding. This type of encoded information enables the models 320 to learn complex relationships between application types and hardware configurations, which can then be used to predict optimal settings or upgrades based on new inputs. Table 1 below shows one example of encoding information used as training data 318, with each row representing one training data instance:

TABLE 1

| | | | Display | | |
|---|---|---|---|---|---|
| | | | Reso- | | |
| Game Title | CPU | CPU | lution | . . . | FPS |
| [0, 1 . . . 0] | [84, 2, . . . , 750] | [12, . . . , 95] | 0 | | 220 |
| . . . | [64, 2, . . . 7, 50] | [6, . . . , 105] | 1 | | 230 |
| . . . | [24, 3, . . . , 600] | [4, . . . , 75] | 0 | | 100 |
| . . . | [64, 1, . . . , 675] | [12, . . . , 85] | 0 | | 120 |
| . . . | [128, 1, . . . , 700] | [4, . . . , 95] | 1 | | 212 |

In at least some implementations, the training engine 316 takes as input the training data 318 and the current model metadata 322 and proceeds to train or fine-tune the model(s) 320 based on the training data 318 using one or more machine learning techniques. The training process, in at least some implementations, includes performing one or more machine learning techniques, such as supervised learning, unsupervised learning, reinforcement learning, semi-supervised learning, transfer learning, ensemble learning, or the like, to configure the model(s) 320 to support various optimization goals (e.g., identifying hardware upgrade requirements, optimizing low-level system parameters, or tailoring application-specific settings). During the training process, parameters of one or more machine learning models (individually or in an ensemble) are iteratively updated (e.g., additional adjustments are performed) based on a prediction error computed for that model until a predefined convergence criterion is met. This ensures that the training process dynamically adjusts the models to reduce prediction error and achieve specific outcomes for each type of optimization scenario. The training process dynamically adjusts the parameters of the models to reduce prediction error and ensure that the models learn to achieve specific outcomes for each optimization scenario based on the type of input data used and the expected results.

During the training process, a single model 320 is trained for all optimization modes or one or more different models 320 are trained for each optimization mode or a combination of the optimization modes. In at least some implementations, for the upgrade analysis and recommendation optimization mode, the training engine 316 trains one or more ML models, such as an ensemble model including a Random Forest Regressor, a K-Nearest Neighbor (KNN) Regressor, a LASSO Regressor, and a Dense Neural Network (DNN) to identify hardware upgrade recommendations. Parameters for each model in this ensemble are updated independently based on the prediction error for the corresponding model, allowing each model to learn its unique contribution to the optimization problem. This training process continues until a convergence criterion, such as validation loss stabilization, is satisfied for each model. The training data 318 for this ensemble model includes, for example, encoded information similar to the encoded information 220 described above with respect to FIG. 2. In at least some implementations, each instance of encoded information 220 includes an encoding of a game or application title, an encoding of a CPU, an encoding of a GPU, an encoding of a display resolution, and a performance metric (e.g., FPS, lag, video quality, etc.) for the game or application resulting from this combination of hardware components. The training data 318 includes multiple different instances of such encoded information.

In at least some implementations, if an ensemble of models is implemented, the models 320 are each trained independently using the same training data 318 to learn distinct aspects of the optimization problem. In at least some implementations, the models 320 support multiple input-output mappings to predict different hardware components based on provided vector combinations. For example, in some configurations, a model 320 is trained to predict a GPU based on a given CPU, display, and game vector; predict a CPU based on a given GPU, display, and game vector; or predict a display based on a given CPU, GPU, and game vector. This flexibility allows the IOC 130 to generate diverse hardware recommendations depending on the user's current configuration and desired performance metrics.

The Random Forest Regressor model in the ensemble is trained, for example, to identify patterns in hardware configurations and performance metrics using a supervised learning or another approach. During training, the model constructs multiple decision trees, each trained on a random subset of the training data 318, allowing it to handle categorical data and capture non-linear dependencies between input features (e.g., GPU core count, CPU clock speed, memory bandwidth) and performance outcomes (e.g., FPS, latency).

The training process involves optimizing various hyperparameters, such as the number of estimators (trees), depth of trees, and the split criteria using a grid search approach. For example, a grid search is used to identify the optimal number of trees, the maximum depth for each tree, and the function used to evaluate the fitness of tree splits (e.g., using log or sqrt functions). By using a grid search, the model tests various combinations of these parameters to determine the set that produces the best results for accurately predicting performance across a variety of configurations, whether predicting GPU, CPU, or display parameters based on the input encodings.

This hyperparameter tuning ensures that the Random Forest Regressor can generalize well to new hardware setups while minimizing overfitting. The model then combines the results from each decision tree to produce an aggregated prediction, which represents the most likely performance outcome for a given hardware configuration and set of input parameters. This aggregation approach (e.g., averaging or majority voting) enhances the robustness and reliability of the model's predictions, making it suitable for various optimization scenarios (e.g., predicting GPU performance based on a given CPU, game, and display configuration).

The K-Nearest Neighbor (KNN) Regressor model, in at least some implementations, is trained using a supervised learning or another approach to cluster similar hardware configurations and performance profiles using a simple K-Nearest Neighbor algorithm. During training, the KNN Regressor takes encoded input vectors (e.g., vector representations of games, CPUs, GPUs, etc.) along with known performance outcomes (e.g., FPS values) from the training data 318 and learns to associate each input with its closest known configuration in the dataset.

By applying a distance metric (e.g., Euclidean or cosine distance), the KNN Regressor learns to map the input encodings to the nearest clusters or configurations, enabling it to provide accurate predictions for new hardware setups not part of the training data. This approach is effective for identifying the most similar configurations and generating baseline predictions for diverse hardware and application combinations. For example, when the KNN Regressor is trained to predict GPU clusters, it learns to identify which GPU cluster a given CPU and game combination is most closely associated with, based on patterns in the training data. Similarly, when trained to predict CPU or display clusters, the KNN Regressor learns to find the closest matching configuration for the other components, supporting diverse input-output mappings. The resulting model is then used to provide recommendations or predictions for new hardware configurations by comparing them to the learned clusters in the training data.

The LASSO Regressor model, in at least some implementations, is trained using a train-test split strategy with an alpha value (e.g., 0.1) to control the degree of regularization during training. The alpha value is set to balance between minimizing the loss function and performing feature selection, where higher alpha values would lead to stronger regularization (driving more feature weights to zero). During training, this regularization helps the model focus on the most relevant features in the training data (e.g., CPU core count, memory bandwidth, etc.) by driving less impactful features' weights to zero, effectively filtering out noise and irrelevant data. The LASSO Regressor's training process ensures that the model accurately identifies and prioritizes the most influential hardware and configuration parameters for predicting performance under various conditions.

For example, the LASSO model is trained to consider attributes such as GPU clock speed, CPU cache size, and memory latency for scenarios like predicting FPS for a game or recommending upgrades to reduce latency. After training, the LASSO Regressor's output is used to identify which hardware attributes (e.g., GPU clock speed, CPU cache size) are needed for different optimization scenarios (e.g., upgrade analysis, system parameter tuning), improving overall model interpretability by reducing complexity in the learned feature space.

In at least some implementations, the DNN is trained using a deep learning approach to perform regression-based predictions for specific hardware components or system configurations (e.g., GPU, CPU, display, application settings, etc.) based on input vectors. The training process involves using a dataset that includes encoded representations of game titles, hardware specifications, and target performance metrics to enable the network to learn complex patterns and relationships within the data.

The DNN, in at least some implementations, is initially configured with three hidden layers and one output layer, although in other implementations, the DNN includes fewer or additional hidden layers and varying numbers of output layers, depending on the complexity of the optimization task and the specific predictions being targeted. During training, each hidden layer in the network is configured to progressively reduce the dimensionality of the input data while capturing non-linear interactions between input features.

The hidden layers, in at least some implementations, are structured with a decrementing neuron count to effectively learn hierarchical representations. For example, in some configurations, the first hidden layer has 1024 neurons, the second hidden layer has 512 neurons, and the third hidden layer has 256 neurons. However, other neuron configurations are also applicable depending on the desired complexity and optimization requirements. Each hidden layer, in at least some implementations, employs a ReLU (Rectified Linear Unit) activation function, allowing the network to learn complex, non-linear relationships in the encoded input data that simpler models may not capture.

The output layer is configured to have a number of neurons (e.g., 9 neurons) corresponding to the number of predicted values for a given hardware component(s) or optimization scenario. The final output layer utilizes a linear activation function to produce continuous-valued predictions (e.g., FPS, power consumption, latency, etc.) based on the input vectors, ensuring that the model can generate precise numerical outputs. The training process includes scaling and normalizing the inputs and outputs using techniques such as a Standard Scalar to maintain consistency across different data ranges. After training is complete, the DNN is able to take real-time and other input data and perform inference to generate performance predictions. Once the raw output is produced, it is scaled back to its correct range, and then the values are bucketed to the closest known hardware or configuration profile (e.g., GPU, CPU, etc.) using a cosine distance metric, ensuring that the predicted profile is aligned with real-world configurations.

In at least some implementations, the training engine 316 trains the model(s) 320 for the system parameter tuning optimization mode using one or more machine learning approaches to address optimization goals. For example, in at least some implementations, these models 320 are configured to optimize low-level system parameters, such as clock speeds, voltages, and power budgets, to achieve specific performance targets while maintaining system stability. The training process for these models 320 involves using one or more machine learning approaches depending on the complexity of the system parameters and the desired outcomes. For example, reinforcement learning (RL), supervised learning, or a combination of both may be applied to train the models 320 to adjust and refine system parameters dynamically in response to real-time data.

The training engine 316 dynamically determines when to stop training each model in the ensemble based on predefined convergence criteria tailored to the specific machine learning models being employed. These stopping criteria include, for example, validation loss convergence, gradient-based convergence, or performance-based goals, depending on the model type and optimization objectives. For models such as DNN and LASSO Regressor, the training engine 316, in at least some implementations, monitors the validation loss on a separate validation dataset and halts training when the loss stabilizes or meets a predefined threshold. Early stopping is also used to prevent overfitting, where the training process stops if there is no improvement in validation loss over a predefined number of iterations (e.g., a patience value of 10 epochs).

For models such as the Random Forest Regressor, the training engine 316, in at least some implementations, uses out-of-bag (OOB) error as a primary indicator for determining when to stop adding decision trees. The training engine 316 monitors the GOB error and halts the training of additional trees once the error stabilizes and no further improvement is observed. For the KNN Regressor, the training engine 316, in at least some implementations, iterates through different values of kk (the number of nearest neighbors) and evaluates the model's performance using cross-validation until the optimal kk-value is found. This ensures that the training is fine-tuned to identify the best-fit parameters for the hardware configurations being optimized.

In at least some implementations, an ensemble-specific criterion is used to ensure that the models' predictions in the ensemble converge to a stable consensus before halting the training process. The training engine evaluates whether the predictions generated by the individual models are consistent and aligned with the overall performance goals. If multiple models in the ensemble produce reliable and similar predictions for a given hardware configuration or optimization goal, training is stopped to prevent overfitting and resource inefficiency.

When training the models 320 for the system parameter tuning optimization mode, the training data 318 includes, for example, a range of encoded hardware descriptors (e.g., CPU, GPU, memory configurations, etc.) and corresponding system states, such as temperature, power consumption, and performance metrics (e.g., FPS, latency, etc.). The dataset captures varying configurations and their impact on performance, power, thermal stability, and system stability under one or more workload scenarios, including gaming, multimedia editing, and rendering. When using reinforcement learning, the training data 318, in at least some implementations, also includes a reward structure based on achieving performance targets while staying within stability constraints, such as avoiding thermal throttling or exceeding power budgets.

In at least some implementations, different types of models are used for system parameter tuning. For example, RL models are employed to optimize parameters iteratively, adjusting clock speeds, voltages, and power limits dynamically to achieve desired performance levels. For each adjustment, the model receives a reward based on meeting target metrics, such as FPS or power efficiency, while penalizing negative outcomes such as system crashes or throttling. In at least some embodiments, supervised learning models, such as Random Forest Regressors and DNNs, are trained using labeled data where each configuration is mapped to a specific performance outcome. These models predict performance and stability based on different system parameter combinations. In another example, ensemble models, including Random Forest, KNN, and LASSO Regressors, are trained in parallel to capture different aspects of system parameter tuning, such as stability prediction and performance impact. In at least some implementations, the results from these models are aggregated to produce a single recommendation for optimal tuning.

The trained models generate optimization profiles 222 including tuning profiles specifying recommended parameter settings, such as core clock, memory clock, voltage, and power budget, for the processing system 100. In at least some implementations, these outputs are evaluated for stability and power efficiency to ensure that the recommended settings deliver the desired performance without compromising system integrity. The optimization goals, in at least some implementations, focus on balancing between maximizing performance (e.g., FPS) and minimizing power consumption. During training, the models learn to predict scenarios where overclocking leads to diminishing returns or causes instability and adjust their recommendations accordingly.

In at least some implementations, the training engine 316 trains the model(s) 320 for the application setting optimization mode to determine the optimal application settings (e.g., resolution, anti-aliasing, texture quality, etc.) for a given hardware configuration to provide the best possible user experience. The training process in this mode focuses on, for example, mapping specific application settings to user-defined performance or visual quality goals using machine learning approaches, such as supervised learning and transfer learning.

The training data 318 for the application setting optimization mode includes, for example, encoded application-specific descriptors, such as game genres and visual quality requirements, as well as hardware configurations, including GPU and CPU encodings and display resolution. In at least some implementations, performance metrics, such as FPS, latency, and visual fidelity, are included as target values for different settings. The dataset covers a variety of application settings and their corresponding performance outcomes on different hardware configurations, allowing the models to capture the impact of changing settings on performance and visual quality.

The models 320 trained for the application setting optimization include supervised learning models, such as Random Forest Regressors and DNNs, which predict how different application settings impact performance metrics based on the current hardware configuration. Transfer learning models, in at least some implementations, are also used to adapt pre-trained models to new applications or hardware configurations when only limited training data is available. These models start with a baseline and are refined using additional labeled data for the new application or hardware setup. DNNs, in at least some implementations, are trained to learn complex interactions between application settings and the underlying hardware, capturing non-linear relationships beneficial for visual quality optimization.

The trained models 320 produce optimization profiles 222 that recommend application-specific settings, such as resolution, texture quality, shadow quality, and the like, tailored to the user's current hardware configuration. These profiles 222, in at least some implementations, are dynamically updated during real-time gameplay or application execution to adapt to changing conditions, such as varying GPU or CPU loads. The optimization goals focus on balancing between different user-defined goals, such as high FPS for competitive gaming and high visual quality for single-player experiences. For example, reducing texture quality may increase FPS without significantly impacting visual fidelity in a fast-paced game, whereas maintaining high shadow quality may be prioritized in a cinematic game.

In some implementations, a single model 320 is trained to support multiple optimization goals by using a multi-task learning approach. This enables the model 320 to predict both system parameters and application settings based on a unified training dataset. In other implementations, separate models 320 are trained for each optimization type, allowing more specialized learning for each scenario. For complex scenarios involving multiple optimization goals, an ensemble of models 320 is used. Each model 320, such as Random Forest, DNN, and KNN, is trained independently on the same training data and then combined to produce a final optimization profile based on a weighted aggregation of individual predictions. The ensemble approach helps ensure robustness and generalizability, particularly when predicting the impact of multiple settings or configurations simultaneously.

The final optimization profiles 222 generated by these models 320, in at least some implementations, are fine-tuned based on user feedback or additional training data 318 to improve accuracy for specific applications or hardware configurations. Transfer learning techniques, in at least some implementations, are applied to update pre-existing models 320 with new data, enabling the system to adapt to evolving hardware and software environments.

In at least some implementations, an ensemble network, similar to the one described above for the upgrade analysis and recommendation optimization mode, is implemented for one or both of the system parameter tuning optimization mode or the application setting optimization mode. In at least one configuration, this ensemble combines multiple models, such as Random Forest, KNN, LASSO, and Dense Neural Networks, to provide a comprehensive approach for complex tuning or setting optimization scenarios. Each model 320 in the ensemble focuses on distinct aspects of the optimization problem, such as predicting stability, performance impact, or resource utilization. The ensemble network enables the system to leverage the strengths of various models, improving robustness and ensuring that diverse system or application settings are optimized simultaneously. For example, the ensemble is used to tune multiple parameters concurrently (e.g., clock speeds, power limits, and memory timings) in system parameter tuning or adjust multiple application settings (e.g., resolution, texture quality, shadow quality, etc.) in application setting optimization, while taking into account complex interactions between the settings and hardware components. By aggregating predictions from each model 320, the ensemble network helps provide reliable recommendations that balance between performance, stability, and user experience.

In at least some implementations, the training engine 316 dynamically determines when to stop training each model in the ensemble based on predefined convergence criteria tailored to the specific machine learning models being employed. These stopping criteria include, for example, validation loss convergence, gradient-based convergence, or performance-based goals, depending on the model type and optimization objectives. For models such as DNN and LASSO Regressor, the training engine 316, in at least some implementations, monitors the validation loss on a separate validation dataset and halts training when the loss stabilizes or meets a predefined threshold. Early stopping is also used to prevent overfitting, where the training process stops if there is no improvement in validation loss over a predefined number of iterations (e.g., a patience value of 10 epochs).

For models such as the Random Forest Regressor, the training engine 316, in at least some implementations, uses out-of-bag (OOB) error as a primary indicator for determining when to stop adding decision trees. The training engine 316 monitors the GOB error and halts the training of additional trees once the error stabilizes and no further improvement is observed. For the KNN Regressor, the training engine 316, in at least some implementations, iterates through different values of kk (the number of nearest neighbors) and evaluates the model's performance using cross-validation until the optimal kk-value is found. This ensures that the training is fine-tuned to identify the best-fit parameters for the hardware configurations being optimized.

In at least some implementations, an ensemble-specific criterion is used to ensure that the models' predictions in the ensemble converge to a stable consensus before halting the training process. The training engine evaluates whether the predictions generated by the individual models are consistent and aligned with the overall performance goals. If multiple models in the ensemble produce reliable and similar predictions for a given hardware configuration or optimization goal, training is stopped to prevent overfitting and resource inefficiency.

When training RL models, such as for system parameter tuning or application setting optimization, the training engine 316 uses a reward-based convergence criterion. The RL models are trained using an iterative process in which the training engine 316 evaluates a reward function based on system performance metrics (e.g., FPS, power efficiency, latency, input lag, visual quality, etc.) and stability outcomes (e.g., avoiding crashes, thermal throttling, etc.). Training is halted when the cumulative reward converges to a stable value or when a predefined number of episodes has been reached without further improvement. This approach helps ensure that the RL models achieve optimal system parameters without overfitting or compromising system stability.

In at least some implementations, the training engine 316 generates multiple different sets of model metadata 322. In these implementations, the training engine 316 trains multiple models 320 for each of a plurality of different configurations of the processing system 100 and stores their resulting model metadata 322 in the designated portion 304 of the system memory 110. For example, the training engine 316 trains a first model 320 for a first configuration of the processing system 100, where the system has a specified hardware configuration (e.g., CPU, GPU, display, etc.), along with a defined set of application settings. The training engine 316 then stores the resulting model metadata 322 associated with this first trained model 320. Subsequently, the training engine 316 trains a second model 320 for a different configuration in which the processing system 100 has the same hardware configuration, but a different set of application settings or system parameters. The resulting model metadata 322 from this second model 320 is also stored in the system memory 110. As such, the inference engine 312, in at least some configurations, implements different models 320 having varying model metadata 322 depending on the current state of the processing system 100.

Even though the above description discusses an implementation utilizing an ensemble of models as an example, the techniques described herein are not limited to using ensembles. Other machine learning modules and algorithms, including neural networks, support vector machines (SVM), gradient boosting machines (e.g., XGBoost), linear regression models, logistic regression models, clustering algorithms such as K-means, and the like, can also be employed.

As indicated above, the inference engine 312, in at least some implementations, takes the optimization input 203, including any encoded information/input 220 and user input 201, and the model metadata 322 as input. In other implementations, unencoded versions of the optimization input 203 are provided as input to the inference engine 312. The inference engine 312 uses the model metadata 322 to configure one or more corresponding models 320 for locally performing inference on the optimization input 203 using a runtime engine. For example, the inference engine 312 configures the one or more models 320 using the model metadata 322, and inputs the optimization input 203 into the configured model(s) 320. In at least some implementations, the inference engine 312 implements different models 320 that have been trained for different configurations of the processing system 100, different user-defined optimization criteria (e.g., increased FPS, decreased lag, increased resolution, power efficiency, stability optimization, etc.), and varying operational contexts. The model(s) 320 perform one or more inference operations on the optimization input 203 and generate one or more types of inference outputs depending on the selected optimization mode(s). For example, in the system parameter tuning optimization mode, the inference output includes optimization profiles 222 including optimized system parameters such as core clock, memory clock, voltage, and power budget for at least one hardware component of the processing system 100. In the application setting optimization mode, the inference output includes optimization profiles 222 including recommended application settings, such as resolution, anti-aliasing, and texture quality, for the given application based on the user's hardware and performance goals. In the upgrade analysis and recommendation optimization mode, the inference output includes optimization profiles 222 including hardware upgrade recommendations, such as a GPU or CPU upgrade, to achieve a specific performance target(s).

In at least some implementations, the inference/runtime pipeline 302 includes a post-processor (not shown) configured to process and refine the raw inference outputs generated by the inference engine 312 before generating the final optimization profiles 222. The post-processor is configured to ensure that the optimization profiles 222 produced by the inference engine 312 are actionable, interpretable, and suitable for dynamic implementation by the system components. The post-processor performs various operations on the raw inference outputs depending on the optimization mode(s) currently active in the inference engine 312. In at least some implementations, these operations include scaling and normalization, conflict resolution, scenario-based adjustments, formatting, validation, and the like.

For example, in some implementations, the post-processor takes as input one or more raw outputs from the inference engine 312, such as initial system parameter recommendations or application settings. The post-processor normalizes these outputs to ensure they are within predefined ranges suitable for the target hardware. In at least some implementations, the post-processor performs conflict resolution when multiple optimization profiles 222, generated by different models, include overlapping recommendations. The post-processor uses priority rules or predefined optimization criteria (e.g., power efficiency vs. performance) to refine these recommendations, ensuring that the final output is consistent with the user-defined goals.

Additionally, the post-processor, in at least some implementations, adjusts the inference outputs based on the current operational context of the processing system 100. For instance, if the inference engine 312 outputs a set of performance-optimized tuning parameters (e.g., GPU core clock, memory clock frequencies, etc.) for a gaming application, the post-processor may further adjust these parameters based on whether the processing system 100 is in a high-power or low-power mode. This scenario-based adjustment ensures that the recommended parameters are aligned with the current operating conditions of the system.

The post-processor, in at least some implementations, also formats the final optimization profiles 222 according to a predefined schema or data structure (e.g., JavaScript Object Notation (JSON), Extensible Markup Language (XML), etc.) for seamless integration with other system components. This formatting operation ensures that the optimization profiles 222 can be dynamically applied to the processing system 100 or transmitted to remote devices for implementation.

In some configurations, the post-processor is further configured to validate the refined optimization profiles 222 to ensure they meet predefined stability and safety constraints. For example, the post-processor may verify that recommended GPU clock speeds do not exceed thermal or power limits or that the suggested memory voltages are within acceptable ranges to prevent system instability. By performing this validation step, the post-processor helps prevent potential adverse effects that may arise from applying inappropriate or conflicting settings.

In at least some implementations, the prediction unit 212 further includes an optimizer 314, which works in conjunction with the inference engine 312 to dynamically implement or adjust the optimization profiles 222 generated for the processing system 100. The optimizer 314, in at least some implementations, monitors real-time system conditions and applies the optimization profiles 222 depending on the operational context, such as active applications, system load, and user-defined performance goals. By leveraging the outputs from the inference engine 312, the optimizer 314 selectively applies tuning parameters (e.g., clock speeds, power budgets, memory configurations, etc.) to system components to achieve the desired performance targets.

The optimizer 314 operates as an intelligent feedback loop that continuously monitors the effectiveness of the applied parameters, making real-time adjustments to ensure the system maintains optimal performance without overutilizing resources. For example, if the inference engine 312 outputs a recommended GPU configuration for a game that initially suggests higher resource allocation based on predicted rendering load, the optimizer 314 monitors the in-game activity. If the gameplay transitions to a less demanding scenario, such as moving to a static or low-action scene, the optimizer 314 dynamically reduces the tuning parameters to conserve power and maintain stability. Conversely, when the game transitions to a high-action sequence with complex graphics rendering, the optimizer 314 ramps up the GPU parameters based on the stored optimization profiles 222 to ensure smooth and responsive gameplay.

In at least some implementations, the optimizer 314 not only manages GPU or CPU settings but also adjusts application-specific settings in real-time, such as texture quality, anti-aliasing, and resolution. By dynamically switching between various optimization profiles 222 generated by the inference engine 312, the optimizer 314 ensures that the user-defined goals, such as achieving high FPS for competitive gaming or maintaining high visual fidelity for single-player experiences, are achieved without compromising system integrity. Furthermore, in the upgrade analysis and recommendation mode, the optimizer 314 evaluates the impact of hardware changes on overall performance and updates the optimization profiles 222 accordingly.

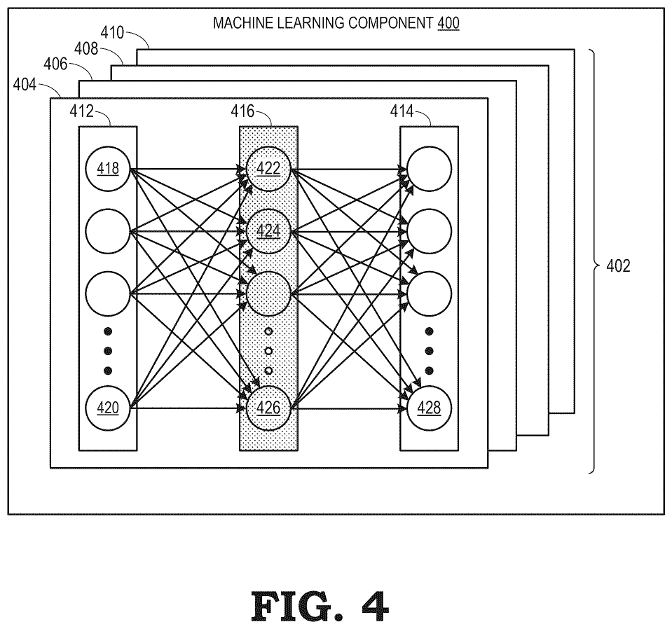

As described above with respect to FIG. 3, the IOC 130 performs one or more machine learning operations to generate optimization profiles 222. Therefore, in at least some implementations, one or more components of the IOC 130 are ML modules or include ML module(s) that implement one or more machine learning models 320. FIG. 4 shows one example of an ML module(s) 400 capable of being implemented as or by one or more components of the IOC 130, such as the prediction unit 212 or the training engine 316. The ML module(s) 400, in at least some implementations, is composed of an ensemble of ML models 320 (also referred to herein as “ensemble 402”). The ensemble 402, in at least some configurations, includes one or more deep neural networks (DNNs) and other types of machine learning models, such as convolutional neural networks (CNNs), recurrent neural networks (RNNs), and traditional models, such as Random Forests, LASSO regressors, and KNN regressors. These models are used for determining system parameters, application-specific settings, and hardware optimization profiles tailored to one or more of the configuration of the processing system 100, workload characteristics, hardware specifications, user-defined optimization criteria, and the like.

During training, as described above with respect to FIG. 3, the ensemble 402 adaptively learns from a variety of training data sets 318, such as user input 201 (e.g., performance metrics to improve) and optimization input 203 (e.g., encoded configuration information 214, application information 216, hardware configuration information 218, etc.) to generate optimization profiles 222 for various operational contexts. Once trained, the ensemble 402 is capable of runtime learning, where it continues to refine its internal parameters based on real-time feedback and operational data. This enables the ML module(s) 400 to dynamically adjust its optimization profiles or refine its model parameters to account for new or unforeseen operational scenarios during runtime.

In the depicted example, the ensemble 402 includes several machine learning models, such as a DNN 404, a Random Forest regressor/model 406, a KNN regressor/model 408, and a LASSO regressor/model 410. These models, in at least some implementations, operate individually, in combination, or as part of the ensemble 402 during the different optimization modes (e.g., system parameter tuning, application setting optimization, and upgrade analysis). In at least some implementations, depending on the operational context, other ML models, such as CNNs, RNNs, and support vector machines (SVMs), are employed alone or in combination with the ensemble 402 to perform complex optimization tasks that involve diverse inputs and varying optimization goals.

In the system parameter tuning optimization mode, the ML module(s) 400, during runtime, utilizes the ensemble 402, other ML models, or a combination thereof to dynamically adjust low-level system parameters, such as clock speeds, voltages, and power limits, in response to real-time input metrics, such as component temperatures and power consumption. For example, the DNN 404 within the ensemble 402 analyzes complex, multi-dimensional input data, capturing non-linear relationships between hardware parameters and current operating conditions to predict and suggest fine-grained adjustments. The Random Forest model 406 evaluates stability and performance impacts, while the KNN model 408 identifies past configurations that performed optimally under similar conditions. The LASSO model 410 focuses on isolating the most impactful parameters, such as a specific voltage or power setting, to fine-tune system stability. In at least some implementations, additional ML models, such as RNNs or CNNs, are included to capture temporal dependencies or visual patterns in input data (e.g., thermal imaging for hot spots) for more complex optimization scenarios. This allows the ML module 400 to adapt the configuration of the processing system 100 configurations dynamically, balancing performance and stability in real-time based on varying workloads or user-defined performance targets.

In the application setting optimization mode, the ensemble 402, other models, or a combination thereof work together to recommend the optimal software and display settings based on current hardware configurations and user preferences. For example, the DNN 404 processes real-time gameplay or application-specific input data to predict the visual quality or performance impacts of different settings, such as resolution, anti-aliasing, and texture quality. The Random Forest model 406 evaluates the power efficiency and thermal stability of these settings, while the KNN model 408 references past configurations to find the closest matches that meet user-defined quality goals. The LASSO model 410 minimizes irrelevant features to prioritize the most impactful settings. Additionally, in at least some implementations, CNN models are used for image-based quality assessments, while RNN models are used for tracking gameplay sequences and suggesting dynamic adjustments based on real-time game events. This allows the ML module(s) 400 to fine-tune application settings based on complex, real-time data patterns, ensuring an optimal user experience that balances high-quality visuals and smooth gameplay depending on the user's goals (e.g., competitive FPS gaming vs. high-quality single-player experiences).

In at least some implementations, the ML module 400 implements different neural network architecture configurations or combinations of models based on the specific optimization scenario. As an example, during system parameter tuning, a combination of the DNN 404 and an RNN are employed to capture both static and dynamic relationships between the hardware components and system states, while a CNN, in some instances is added for application setting optimization to extract visual features that affect display performance. In other implementations, an ensemble of RNNs, Random Forest models 406, and KNN models 408 are used together to track temporal changes and provide stability and performance recommendations that adjust dynamically based on evolving workloads.

The outputs from these various models are then aggregated into an array, and based on the consensus of multiple predictions, one or more optimization profiles 222 are generated that include optimized settings, adjustments, or recommendations for the processing system 100. For example, in the upgrade analysis and recommendation optimization mode, if multiple models suggest upgrading the GPU to a higher-performing model given the current CPU and display settings to achieve smoother gameplay, or replacing the CPU to reduce latency for a specific game, those upgrade recommendations are considered reliable and prioritized.

In the system parameter tuning mode, the aggregated outputs can be used to generate optimization profiles that suggest specific adjustments to hardware parameters (e.g., voltage, clock speeds, or power limits) for the current workload. For instance, if a Random Forest model 406 indicates that reducing the CPU clock speed will minimize power consumption without significantly impacting performance, while the KNN model 408 suggests a different voltage setting to improve stability under thermal constraints, these recommendations can be weighted and combined to create an optimal parameter configuration. Similarly, the DNN 404 can predict the impact of dynamic frequency scaling on system stability and performance for an active workload, while the LASSO model 410 focuses on fine-tuning individual voltage or power settings to achieve a specific power efficiency target. The generated optimization profile(s) 222 can then be used to implement the suggested changes dynamically, thereby adapting the system configuration in real-time to maintain performance and stability under varying operational conditions.

In the application setting optimization mode, the outputs of the ensemble 402 and other models are used to recommend ideal software and application settings based on the real-time operational context. For example, if multiple models indicate that reducing the texture quality and adjusting the anti-aliasing settings will maintain a target frame rate without compromising visual quality, while the KNN model 408 identifies similar settings used successfully in past configurations, the combined predictions are used to generate an application-specific profile. This optimization profile 222 can include recommendations for display resolution, frame rate limits, and rendering options tailored to the current hardware configuration and the user's visual quality preferences. The DNN 404 can also evaluate the impact of dynamic adjustments to these settings during different gameplay scenarios, ensuring that the application settings are adapted on-the-fly to balance high-quality visuals and performance.

In the example shown in FIG. 4, the DNN 404 is illustrated as one type of machine learning model used within the ensemble 402, and it includes an input layer 412, an output layer 414, and one or more hidden layers 416 positioned between the input layer 412 and the one or more output layers 416. Each layer is composed of interconnected nodes (e.g., neurons and/or perceptrons) that perform independent computations. A neuron processes input data to produce a continuous output value, such as a real number between 0 and 1, while a perceptron performs linear classifications on the input data, such as a binary classification. Each node in a layer receives input data from one or more nodes in a preceding layer, applies a set of learned weights and coefficients, and generates output data that is passed forward to nodes in subsequent layers based on the layer's connection architecture. During runtime, these layers work together to map complex input data patterns (e.g., real-time CPU/GPU metrics) to optimized system parameters.

As an example, during runtime, node 418 of input layer 412 receives CPU clock speed data, while node 420 receives GPU utilization metrics. In this example, after processing these inputs, node 418 passes its processed output data to hidden layer nodes 422 and 424, while node 420 passes its processed data to hidden layer node 426. The process continues through each hidden layer 414, with the nodes applying activation functions and connection weights learned during training to generate an accurate real-time prediction at one or more output layer nodes 428. The final output values depend on the optimization mode. For instance, in the system parameter tuning optimization mode, the output values are used to adjust one or both of hardware or system configuration settings, such as clock frequency, VRAM frequency, voltage, power, and the like. In the application setting optimization mode, the output values are used to recommend or apply ideal software settings (e.g., resolution, anti-aliasing, texture quality, etc.) for the current hardware configuration to achieve, for example, a performance metric(s) indicated by a user. In the upgrade analysis and recommendation optimization mode, the output values indicate recommended hardware changes, such as a new GPU, CPU, or memory configuration to improve overall system performance based on the current workload and application profiles.

Also, while FIG. 4 illustrates the structure of a DNN 404, the other machine learning models (e.g., Random Forest 406, KNN 408, and LASSO 410) included in the ensemble 402 are constructed with different architecture types. For example, the Random Forest model 406 comprises multiple decision trees, where each tree has been trained on a subset of features, and predictions are made by aggregating the outputs of each tree. Similarly, the KNN model 408 represents trained data points as nodes and performs classifications or regressions based on the distance to the nearest neighbors. The LASSO model 410, in contrast, applies linear modeling with L1 regularization to select and weight the most relevant features. Therefore, while the DNN 404 relies on layers and node connections to process input data, the structure of the Random Forest, KNN, and LASSO models is defined by their unique architecture and learning mechanisms rather than interconnected layers of nodes.

In at least some implementations, the ensemble 402 is configured to select a specific model type based on the characteristics of the optimization problem. For example, the DNN 404 is well-suited for analyzing non-linear patterns in complex, high-dimensional data, while the Random Forest model 406 is effective for handling categorical data and identifying dominant features. The KNN 408 model is useful when the similarity between configurations needs to be evaluated, and the LASSO model 410 is employed for scenarios where feature selection is used for performance optimization. Each model type, whether a neural network or a traditional regressor, has a distinct configuration tailored to the type of optimization (e.g., system parameter tuning, application setting optimization, or upgrade analysis).

In at least some implementations, the device or component implementing the ML module(s) 400 locally stores some or all of a set of candidate ML model configurations that the ML module 400 can employ. For example, in at least some implementations, a component of the IOC 130 indexes these candidate ML models and their corresponding architecture configurations using a look-up table (LUT) or other data structure that takes as inputs one or more parameters, such as system-related configurations of the processing system 100, current workload characteristics, hardware specifications, user-defined optimization criteria, a combination thereof, or the like. Based on these inputs, the LUT or similar structure outputs an identifier associated with a corresponding locally-stored model or combination of models suited for operation in view of the input parameter(s). In this manner, the ML module(s) 400 dynamically selects and employs specific models, model combinations, or architectural configurations based on the current operational state of the processing system 100, allowing the IOC 130 to perform one or more machine learning operations that are optimized for the system parameter tuning, application setting optimization, or upgrade analysis optimization modes.

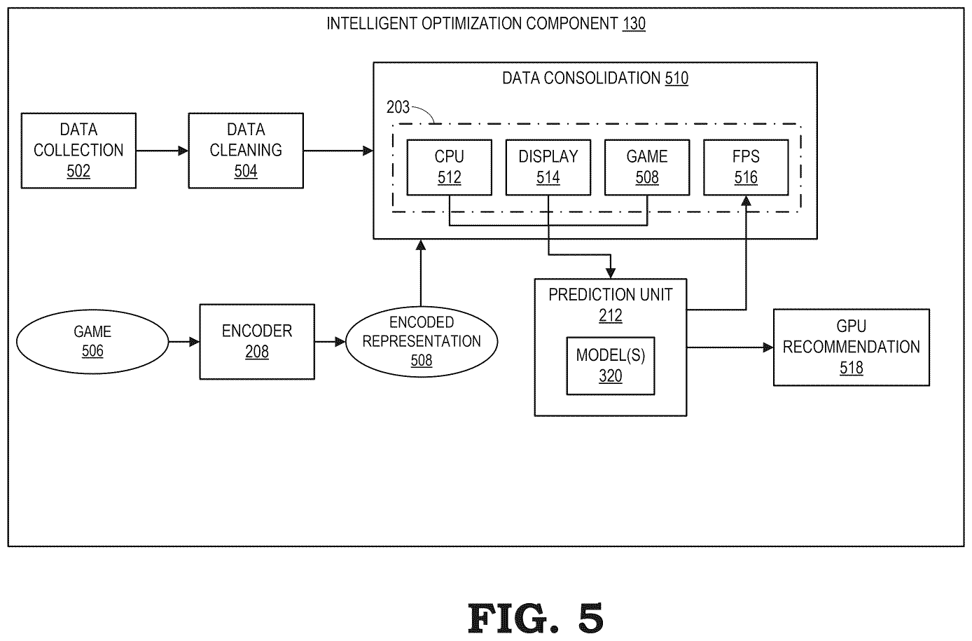

FIG. 5 is a block diagram illustrating an example of the IOC 130 operating in the upgrade analysis optimization mode to recommend a hardware upgrade, such as a specific GPU, CPU, or display, based on user inputs and system configuration data. In at least some implementations, this mode is triggered when a user inputs a new/unseen or current game title along with a performance metric they want to achieve, such as frames per second (FPS) or reduced input lag. The user, in at least some implementations, specifies which hardware component they want to upgrade, or the IOC 130 autonomously determines the optimal component for upgrade based on the current system configuration and performance goals.

In the depicted example, the IOC 130 performs one or more data collection operations 502. For example, the IOC 130 gathers relevant system information, such as the specifications of the CPU, GPU, display, and other hardware components currently installed in the processing system 100. In at least some implementations, the IOC 130 performs one or more data cleaning operations 504 to, for example, normalize, format, and filter the collected information to ensure that the data is consistent and accurate for further processing.

The user or processing system 100 also provides game-specific information 506, such as the game title and genre, as input to the encoder 208, which converts these and other attributes into a structured, numerical representation. This encoded representation 508 is similar to the encoded information 220 described above with respect to FIG. 2 and captures attributes of the game, such as genre (e.g., action, RPG, strategy, etc.), performance targets (e.g., FPS, latency, etc.), a combination thereof, and the like.

The output of the data cleaning operations 504 and the encoded representation 508 of the game are then fed into a data consolidation component 510 of the IOC 130, which combines this information along with other relevant optimization inputs 203. The example inputs illustrated in FIG. 5 include encoded representations of the current CPU 512, current display 514, the game title 506, and one or more monitoring/target variables 516. In at least some implementations, the monitoring variable 516 is a performance metric(s), such as FPS or input latency, provided by the user or determined by the IOC 130. Depending on the type of hardware recommendation being generated, these inputs may vary. For instance, when recommending a GPU upgrade, the input configuration includes, for example, encodings of the current CPU, display, and game title, while a CPU recommendation includes, the input configuration includes, for example, encodings of the current GPU, display, and game title. Similarly, if the IOC 130 is determining an optimal display, the input configuration includes, for example, the CPU, GPU, and game title.

The optimization inputs 203 are then passed to the prediction unit 212, which uses one or more ML models 320, such as the ensemble model 402 described above with respect to FIG. 3 and FIG. 4, to predict the impact of different hardware configurations on the desired performance metric. The ensemble model 402 includes multiple machine learning models 320 (e.g., Random Forest, KNN, LASSO, and DNNs), each configured to evaluate distinct aspects of the optimization problem. In the current example, the inputs 203 are processed by each model 320 in parallel, generating multiple predictions based on how different GPUs would perform with the current CPU and display setup for the given game title.

For example, the Random Forest model identifies dominant hardware features and configurations, analyzing patterns in the collected data. The KNN model clusters similar hardware setups and matches the input configuration to its closest known profile. The LASSO model isolates key features that are most relevant for performance prediction (e.g., clock speed, VRAM size, etc.). The DNN captures complex, non-linear interactions between different hardware components and predicts the performance impact of each potential upgrade. For example, the DNN predicts the performance outcome for each potential hardware upgrade.

The ensemble model 402 aggregates the outputs from these individual models and uses a weighted aggregation scheme to consolidate the predictions. The scheme takes into account the reliability of each model's predictions based on past performance and the similarity of the input data to the training data used for each model. For instance, if the Random Forest and DNN models consistently predict similar FPS improvements for a specific GPU, this prediction is given higher confidence compared to conflicting outputs from other models. The weighted aggregation scheme ensures that the ensemble model's final recommendation is robust and considers the strengths and weaknesses of each underlying model.

As described above, the DNN includes multiple hidden layers and an output layer(s), with each layer performing feed-forward operations defined by the following equation:

$${O}_{1 \leq i \leq 3}^{n = 3} = {\sum }_{i = 1}^{n = 3} {( ( {W}_{i}^{T} * ( {O}_{i - 1} * [ 1 - P ( x ) ] ) + {B}_{i - 1} ) , 0 )}_{max} . \qquad ( EQ 1 )$$

This equation defines the operation for each neuron in the hidden layers, where Wᵢ represents the weight matrix, Oᵢ₋₁ is the output from the previous layer, and Bᵢ₋₁ is the bias term. The output values are subjected to a ReLU (Rectified Linear Unit) activation function, which introduces non-linearity and enables the network to capture complex, non-linear relationships between the input features (e.g., CPU type, GPU type, game genre, etc.).

The final layer of the DNN uses a softmax function to generate probability scores for each of the potential GPU upgrade options, given by:

$${( {O}_{4} )}_{i} = \frac{{e}^{{( ( {W}_{4}^{T} * {O}_{3} ) + {B}_{3} )}_{i}}}{{\sum }_{j = 1}^{k = 9} {e}^{{( ( {W}_{4}^{T} * {O}_{3} ) + {B}_{3} )}_{j}}} . \qquad ( EQ 2 )$$

This softmax function ensures that the output probabilities for each GPU sum to 1, providing a normalized probability distribution over all available options. The prediction unit 212 then selects the GPU with the highest probability score as the recommended upgrade.

During runtime, the monitoring/target variable 516, such as FPS or latency, is continuously tracked (e.g., measured) to evaluate how different GPU configurations affect performance. Each time a new GPU is considered, the ensemble model dynamically predicts its effect on the monitoring variable 516, given the current CPU and display setup. For instance, if the monitoring variable 516 is FPS, the component checks how each potential GPU upgrade would impact FPS for the given game. This monitoring variable 516 acts as an inferencing variable that allows the IOC 130 to refine its predictions by comparing the expected values generated by the model to the real-time FPS measurements. If discrepancies are detected, the model dynamically adjusts the prediction parameters using Neural Network (Loss Function and Back Propagation), as described below.

During runtime, the DNN model continuously monitors the real-time performance of the current system configuration to see how the predicted FPS for each potential GPU option matches the target FPS. To refine predictions and adapt to varying game titles or system conditions, the loss function LL is evaluated using the following equation:

$$L = \frac{1}{9} * {\sum }_{i = 1}^{n = 9} {( {O}_{{t}_{i}} - {O}_{{4}_{i}} )}^{2} . \qquad ( EQ 3 )$$

Here, Oₜ is the target output for the given GPU option, and O₄ is the predicted output of the DNN for that option. This loss function measures the squared error between the expected performance and the predicted performance, averaged across all potential GPU options.

During runtime, the DNN model updates its weights using the weight update rule shown below as part of the back-propagation process:

$${W}_{i}^{*} = {W}_{i} - λ \cdot \frac{dL}{{dW}_{i}} . \qquad ( EQ4 )$$

Where λ is the learning rate, and

$$\frac{dL}{{dW}_{i}}$$

is the gradient of the loss function with respect to the weights. This back-propagation process allows the DNN model to dynamically fine-tune its parameters during runtime based on real-world feedback, ensuring that the recommended hardware upgrade is optimal for the current configuration and performance targets.

Once the ensemble model 402 has generated the predicted performance for each GPU option, the outputs are bucketized using a cosine distance metric to identify the closest matching GPU configuration. The component then consolidates the predictions and recommends the GPU that consistently appears across multiple models as the optimal choice. If a specific GPU is predicted by the majority of models (or another threshold number of models) in the ensemble to provide the highest FPS for the given game, it is marked as the recommended upgrade, and the IOC 130 outputs an optimization profile 222 including the GPU (or other hardware) recommendation 518. The final recommended upgrade, such as a specific GPU model, is presented to the user through the user interface 204. In at least some implementations, a detailed analysis of how the new GPU would improve the desired performance metric is also provided to the user.

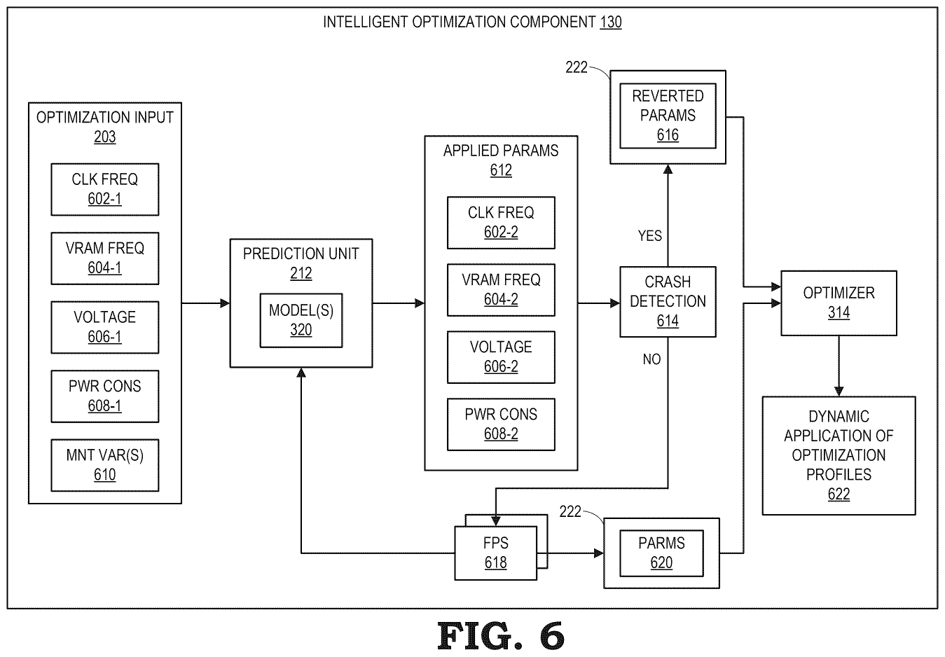

FIG. 6 is a block diagram illustrating an example of the IOC 130 operating in the system parameter tuning optimization mode. In this mode, the IOC 130 dynamically adjusts various GPU parameters during real-time gameplay to achieve the desired performance goals, such as increasing frames per second (FPS) or reducing power consumption. Although this example focuses on GPU tuning, the description is also applicable to tuning other hardware components, such as the CPU 102. In this example, the optimization process begins with the IOC 130 obtaining optimization input 203, such as the current or base system parameters for the GPU 104. These parameters include, for example, the current GPU clock frequency 602-1, current VRAM frequency 604-1, current GPU voltage 606-1, current power consumption 608-1, and the like. In at least some implementations, the optimization input 203 also includes a monitoring variable 610, such as a performance metric(s) (e.g., FPS, input latency, etc.) provided by the user or determined by the IOC 130. This collected serves as the initial baseline values for subsequent optimization.

The IOC 130 provides the optimization input 230 as input to the prediction unit 212 for processing. The prediction unit 212, in this example, implements one or more ML models 320, such as an RL model to optimize the parameters. The RL model, in at least some implementations, is configured using to perform Q-learning and dynamically explores the state space by adjusting one or more of the system parameters at a time, monitoring the performance, and applying a reward-based strategy to fine-tune the GPU settings. The RL model iteratively adjusts parameters, such as clock frequency, VRAM frequency, voltage, and power consumption, individually or in combination, to identify the optimal configuration that maximizes performance (e.g., FPS) without compromising system stability.

In at least some implementations, to intelligently prioritize which GPU parameters to adjust first, the RL model utilizes a multi-arm bandit algorithm to rank and select the most impactful parameters for tuning. The multi-arm bandit algorithm computes a reward value for each parameter adjustment based on historical results (e.g., historical performance impact results) and the observed impact of each parameter on the monitoring variable (e.g., FPS). This reward function is defined by the following equation:

$$Q ( a ) = \frac{{\sum }_{i = 1}^{t} {1}_{( {a}_{t} = a )} * {R}_{i}}{{\sum }_{i = 1}^{t} {1}_{( {a}_{{t}^{=}} a )}} + \sqrt{\frac{2 log t}{{N}_{t} ( a )}} . \qquad ( EQ 5 )$$

In this equation, the first part before the plus sign is a reward computation and the second part after the plus sign is a decay with time computation. Here, a represents the parameter being adjusted (e.g., clock frequency, VRAM frequency, etc.), at denotes the parameter chosen for adjustment at time t, Rᵢ is the reward obtained for adjusting the parameter a, and Nₜ(a) indicates the number of times parameter a has been exploited. The first term in the equation represents the average reward for adjusting parameter a, while the second term, a confidence bound, prioritizes parameters that have been under-explored. This balance between exploiting known high-reward parameters and exploring new parameters allows the RL model to determine which parameter should be adjusted first to achieve the optimal tuning sequence.

After selecting the parameter to tune, the RL model iteratively adjusts it and other system parameters while tracking the effect on the monitoring variable 610, such as FPS. FIG. 6 shows the adjusted and maintained parameters as applied parameter 612, including applied or maintained GPU clock frequency 602-2, VRAM frequency 604-2, GPU voltage 606-2, current power consumption 608-2, and the like. For each adjustment, the RL model follows the Q-learning strategy, updating the parameter values based on observed outcomes and feedback using the following Q-learning equation:

$${Q}_{( s , a )}^{*} = {Q}_{( s , a )} + α ( R + γ * max ( {Q}_{( {s}^{′} , {a}^{′} )} ) - {Q}_{( s , a )} ) . \qquad ( EQ 6 )$$

Here, Q_{(s,a)} is the current state-action value, α is the learning rate for Q-learning, R represents the reward received for taking action a, γ is the discount factor, s′ is the resultant state after taking action a, and Q_{(s′,a′)} is the maximum expected future reward for the next state. This equation enables the RL model to update its understanding of the value of each parameter setting (e.g., clock frequency or voltage) based on the observed outcomes, allowing it to converge towards an optimal tuning configuration.

As the tuning process continues, the monitoring variable 610, such as FPS, is tracked continuously for every parameter adjustment. The IOC 130 also implements a crash detection process 614 to monitor for system instability events or conditions, such as crashes, which indicate that the GPU 104 has become unstable at the current parameter values, jitter, characterized by an oscillation of FPS values (e.g., FPS increasing and then dropping significantly), and FPS drops, where the FPS decreases by more than a predefined threshold (e.g., 5%) over the last N iterations (e.g., 4 iterations), indicating that the system is reaching a suboptimal state. If any of these events occur (indicated by the “yes” branch in FIG. 6), the RL model rolls back the parameter settings to the previous stable configuration before the instability was detected and outputs these reverted parameter values 616. For example, if the current power value is PV(n) and the system crashes, the model rolls back to PV(n−1). The IOC 130 then maintains these stable values in the optimization profile 222.

If a crash or other instability is not detected (indicated by the “no” branch in FIG. 6), the current FPS values 618 (or other performance metric values) are fed back into the prediction unit 212 and the RL model continues to adjust one or more tunable parameters of the GPU 104 to increase performance. The RL model, in at least some implementations, includes an “early stopping” mechanism. For example, if no jitter or FPS drop is detected over a defined number of iterations (e.g., 4), the RL model stops further tuning and outputs the current parameter values 620 as part of the optimization profile(s) 222. This ensures that the system tuning process terminates early if the optimal state is reached, thereby saving computation time and preventing unnecessary adjustments.

In at least some implementations, the IOC 103 implements the optimizer 314 described above with respect to FIG. 3. The optimizer performs one or more operations 622 to dynamically manage the applied tuning parameters (e.g., the reverted parameter values/settings 616 or the early-stop parameters values/settings 620) and outputs adjusted optimization profiles 222. For example, the optimizer 314 monitors real-time system conditions, such as active applications, system load, and GPU utilization, and selectively applies the adjusted parameters to the GPU 104 depending on the real-time operational context. For instance, if the RL model recommends increasing the clock frequency to achieve higher FPS, the optimizer 314 ensures that this change is applied only when the GPU is actively rendering high-intensity scenes. If the game transitions to a lower-action state (e.g., a menu screen), the optimizer 314 dynamically reduces the clock frequency to conserve power and maintain stability. The optimizer 314 operates as an intelligent feedback loop that continuously monitors the effectiveness of the applied parameters, making real-time adjustments to the optimization profiles 222 to ensure that the system maintains optimal performance without overutilizing resources. In at least some implementations, the optimizer 314 dynamically switches between various optimization profiles 222 generated by the prediction unit 212 based on real-time changes in workload conditions or user-defined performance goals.

In at least some implementations, the optimizer 314 leverages a driver tuning function to dynamically apply the adjusted game specific settings, which are controllable by the device driver. This function is defined as:

$$Graphics Driver Tuning = \{ x \vert max ( f ( x ) ) ; 1 \leq x \leq {2}^{n} \} . \qquad ( EQ 7 )$$

Where x represents the tuning values for the game specific settings, f(x) is a function that represents the FPS value or another performance metric for a given set of tuning values, and n is the number of software parameters being optimized. The optimizer 314 continuously evaluates f(x) during gameplay to identify the optimal x that maximizes the desired performance metric, ensuring that the GPU operates within safe limits while achieving the target performance goals. By integrating the multi-arm bandit approach, Q-learning, and dynamic driver tuning, the IOC 130 effectively optimizes GPU performance during gameplay in a stable and efficient manner.

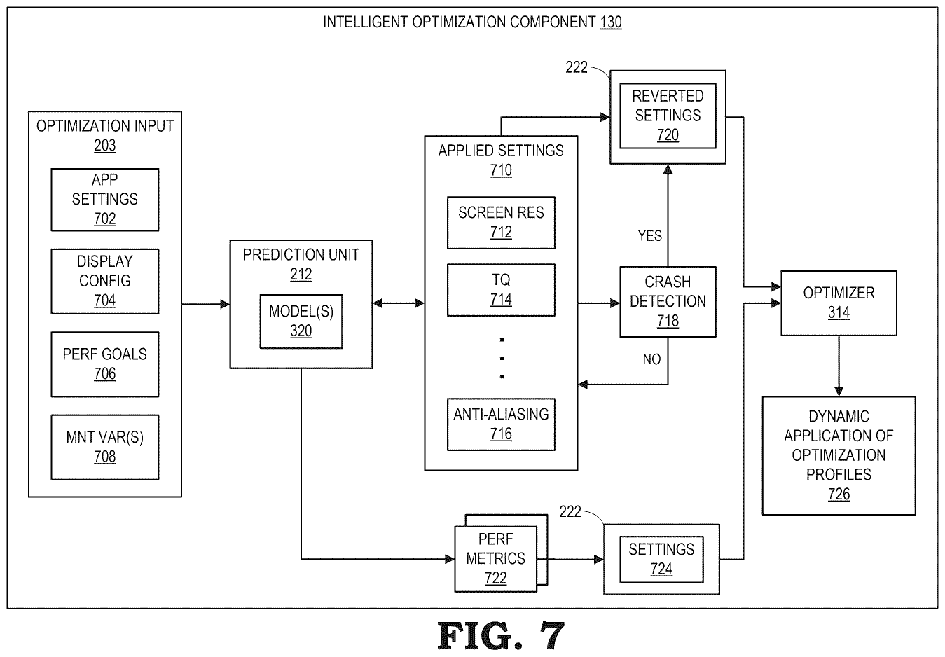

FIG. 7 is a block diagram illustrating and example of the IOC 130 operating in the application setting optimization mode. In this mode, the IOC 130 dynamically adjusts various application-specific settings during real-time gameplay or application execution to achieve the desired performance and visual quality goals specified by the user or processing system 100. In at least some implementations, this optimization mode focuses on modifying software settings, such as screen resolution, texture quality, anti-aliasing, frame rate limits, and other tunable graphics parameters, instead of low-level hardware parameters, such as clock speeds and voltages as shown in FIG. 6. The process ensures that the user's preferences, such as high FPS for competitive gaming or maintaining high visual fidelity for single-player experiences, are met without compromising system stability or performance.

In at least some implementations, the optimization process begins with the IOC 130 obtaining optimization inputs 203. These optimization inputs 203 include, for example, initial application configuration inputs, such as current application settings 702 (e.g., resolution, texture quality, anti-aliasing settings, etc.), base display configuration 704 (e.g., screen size, refresh rate, aspect ratio, etc.), one or more user-defined performance goals 706 (e.g., target FPS, target visual quality requirements, etc.), and one or more monitoring variables 708 (e.g., current FPS, frame latency, power consumption, etc.). In at least some implementations, the optimization input 203 also includes real-time system data, such as GPU/CPU utilization or thermal status, which the IOC 130 uses to guide the application tuning process. These inputs are used to establish the baseline settings that serve as the starting point for subsequent optimizations.

The IOC 130 provides the collected optimization input 203 to the prediction unit 212, which implements one or more machine learning models 320, such as an RL model, to fine-tune application-specific settings based on real-time feedback. Similar to FIG. 6, the RL model dynamically explores the state space of tunable settings (e.g., adjusting resolution and texture quality individually or in combination, etc.) and tracks the corresponding changes in the monitored performance metrics (e.g., FPS, latency, visual quality score, etc.). Each adjustment is monitored, and a reward-based strategy is applied to identify the optimal configuration that maximizes user-defined goals (e.g., higher FPS for competitive gaming, etc.) without compromising stability or visual quality.

In at least some implementations, to prioritize which application settings to adjust first, the RL model leverages a multi-arm bandit algorithm, which ranks and selects the most impactful parameters for tuning based on their observed effect on the monitoring variables. The multi-arm bandit algorithm computes a reward value for each parameter adjustment, using EQ 5 described above:

$$Q ( a ) = \frac{{\sum }_{i = 1}^{t} {1}_{( {a}_{t} = a )} * {R}_{i}}{{\sum }_{i = 1}^{t} {1}_{( {a}_{t} = a )}} + \sqrt{\frac{2 log t}{{N}_{t} ( a )}} . \qquad ( EQ 5 )$$

In this example, a represents the application setting being adjusted (e.g., resolution, texture quality, etc.), aₜ denotes the setting chosen for adjustment at time t, Rᵢ is the reward obtained for adjusting the setting a, and Nₜ(a) indicates the number of times the setting aa has been explored. The first term represents the average reward for adjusting setting a, while the second term, a confidence bound, prioritizes settings that have been under-explored. This balance between exploiting known high-reward settings and exploring new settings allows the RL model to determine the optimal tuning sequence that quickly reaches the desired performance or visual quality goals.

After selecting the application setting to adjust, the RL model iteratively adjusts it while tracking the impact on the one or more monitoring variables 708, such as FPS or visual quality scores. FIG. 7 shows these adjusted settings as applied application settings 710, which include the current screen resolution 712, texture quality (TQ) 714, anti-aliasing settings 716, and other tunable graphics settings. For each adjustment, the RL model follows the Q-learning strategy, updating the settings based on observed outcomes and feedback using EQ 6 described above:

$${Q}_{( s , a )}^{*} = {Q}_{( s , a )} + α ( R + γ * max ( {Q}_{( {s}^{′} , {a}^{′} )} ) - {Q}_{( s , a )} ) . \qquad ( EQ 6 )$$

Here, Q_{(s,a)} is the current state-action value, a is the learning rate, R represents the reward received for selecting setting a, γ is the discount factor, s′ is the resultant state after taking action a, and Q_{(s′,a′)} is the maximum expected future reward for the next state. This equation allows the RL model to converge towards an optimal configuration for the application settings based on the user's goals and the current operational context.

As the tuning process continues, the IOC 130 performs one or more monitoring operations 718 to monitor the effect of each adjustment on the monitoring variable 708. In the event of instability or a significant drop in FPS or visual quality (e.g., a decrease of more than a predefined threshold over the last N iterations), the RL model rolls back the settings to the previous stable values/settings 720 before the suboptimal state was detected (indicated by the “yes” branch in FIG. 7). This rollback mechanism ensures that the processing system 100 maintains stability and avoids excessive performance degradation. The IOC 130 maintains this stable configuration of the application values/settings 720 in an optimization profile 222.

If no instability is detected over a defined number of iterations in the current performance metrics 722 (e.g., FPS, visual quality score, input latency, etc.), the system parameters are fed back into the prediction unit 212 (indicated by the “no” branch in FIG. 7). The RL model then continues to adjust one or more tunable settings of the application to further enhance performance. Because application settings can significantly impact metrics, such as, FPS and visual quality, the RL model, in at least some implementations, iteratively adjusts settings such as texture quality, and anti-aliasing to achieve the desired balance. Similar to the example described above with respect to FIG. 6, the RL model, in at least some implementations, includes an “early stopping” mechanism. For example, if no sub-optimal performance, jitter, or significant drop in FPS or the selected performance metric is detected over a predefined number of iterations, the RL model stops further adjustments and outputs the current stable application settings 724 for the current iteration. The IOC 130 maintains these stable values in the optimization profile 222, ensuring that the application operates under optimal settings without unnecessary adjustments. This early stopping mechanism prevents over-tuning and stabilizes the configuration once the desired performance has been achieved.

In at least some implementations, the IOC 130 implements the optimizer 314 described above with respect to FIG. 3. The optimizer 314 performs one or more operations 726 to dynamically manage the applied application settings (e.g., the reverted values/settings 720 or the early-stop settings 724) and outputs or applies the optimization profiles 222. For example, the optimizer 314 monitors real-time application activity, system load, and user performance goals, and selectively applies the adjusted application settings depending on the operational context. For instance, if the RL model recommends increasing texture quality for high visual fidelity, the optimizer 314 ensures that this change is applied only when the GPU 104 is capable of maintaining high FPS. If the application 118 transitions to a resource-intensive scene, the optimizer 314 dynamically reduces the texture quality to maintain stability and prevent FPS drops. The optimizer 314 operates as an intelligent feedback loop that continuously monitors the effectiveness of the applied application settings, making real-time adjustments to the optimization profiles 222 or their application to ensure that the processing system 100 maintains optimal visual quality and performance without overutilizing resources. In at least some implementations, the optimizer 314 dynamically switches between various optimization profiles 222 generated by the prediction unit 212 based on real-time changes in workload conditions or user-defined performance goals.

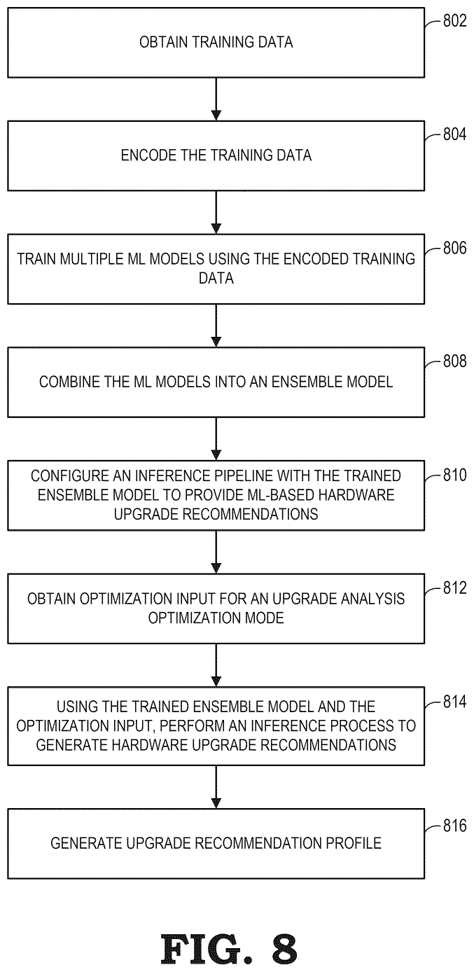

FIG. 8 illustrates a flow diagram of a method 800 for training and utilizing one or more machine learning models to recommend hardware upgrades in the upgrade analysis optimization mode of the IOC 130. The processes described below with respect to method 800 have been described in greater detail with reference to FIG. 1 to FIG. 5 above. For purposes of description, the method 800 is described with respect to an example implementation at the processing device 100 of FIG. 1, but it will be appreciated that, in other implementations, the method 800 is implemented at processing systems having different configurations. Also, the method 800 is not limited to the sequence of operations shown in FIG. 8, as at least some of the operations can be performed in parallel or in a different sequence. Moreover, in at least some implementations, the method 800 can include one or more different operations than those shown in FIG. 8.

At block 802, the IOC 130 obtains training data 318, which includes system configuration information, application-specific data, and performance metrics (e.g., FPS, latency, etc.) for various hardware setups. The collected data 318 serves as a baseline for training on or more ML models 320 to provide accurate upgrade recommendations. At block 804, the IOC 130 encodes the collected training data 318 into numerical vectors to standardize the information and enable efficient model training. In at least some implementations, the data is pre-processed by normalizing values, encoding categorical variables (e.g., game genres), and structuring inputs into a format suitable for training. In at least some implementations, the training data 318 includes encoded system configurations and resulting corresponding performance metric values or operational outcomes.

At block 806, the IOC 130 uses the encoded training data 318 to train multiple ML models 320, such as a DNN 404, a Random Forest model 406, a KNN model 408, and a LASSO model 10. These models are trained to predict the impact of various hardware upgrades on performance metrics based on the current configuration. At block 808, the IOC 130 combines these individual models into a weighted ensemble model 402 that generates consolidated upgrade recommendations. This ensemble model 402 prioritizes the outputs of models that have shown high reliability based on past predictions.

At block 810, the IOC 130 configures an inference runtime pipeline 302 using the trained ensemble model 402 to perform real-time analysis during the upgrade recommendation process. The configuration involves, for example, loading the trained models 320 and configuring runtime settings for efficient inference during real-time operation. At block 812, during runtime, the IOC 130 obtains optimization input 203, such as real-time system configuration information and user-specified performance goals (e.g., target FPS, target reduced input lag, etc.). The optimization input 203 is encoded into the same format used during model training to ensure consistency.

At block 814, the IOC 130 performs inference using the trained ensemble model 402, inputting the encoded information 220 to predict the performance impact of various hardware configurations, such as new CPUs or GPUs. For example, the IOC 130, based on encoded information 220 and a target change in at least one performance metric associated with the application 118 indicated by the user or processing system 100, the IOC 130 selects a hardware component from a plurality of variant types of the same hardware category that achieves the target change. In at least some implementations, the at least one performance metric is measured to obtain a baseline from which performance improvements can be quantified. The baseline metric is used to evaluate the difference between the current system configuration and the predicted outcomes of hardware upgrades, ensuring that the recommended upgrade meets or exceeds the desired performance improvements specified by the user or system.

At block 816, the IOC 130 generates one or more optimization profiles 222 based on the inference results. The optimization profile(s) 222 includes suggestions for hardware upgrades (e.g., a higher-end GPU or CPU) along with estimated performance gains. The generated profile 222 is then presented to the user through a user interface 204 for review and implementation. For example, the generated profile 222 is presented to the user on a display coupled to the processing system 100.

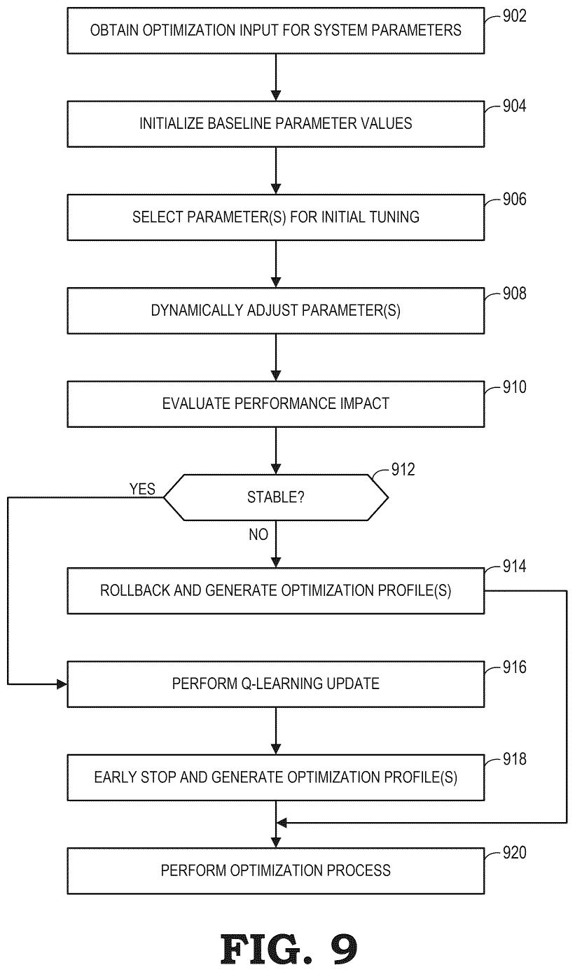

FIG. 9 illustrates a flow diagram of a method 900 for dynamically adjusting system parameters in the system parameter tuning optimization mode of IOC 130. The processes described below with respect to method 900 have been described in greater detail with reference to FIG. 1 to FIG. 4 and FIG. 6 above. For purposes of description, the method 900 is described with respect to an example implementation at the processing device 100 of FIG. 1, but it will be appreciated that, in other implementations, the method 900 is implemented at processing systems having different configurations. Also, the method 900 is not limited to the sequence of operations shown in FIG. 9, as at least some of the operations can be performed in parallel or in a different sequence. Moreover, in at least some implementations, the method 900 can include one or more different operations than those shown in FIG. 9.

At block 902, the IOC 130 collects optimization input 203, such as real-time system parameter inputs, including performance metrics (e.g., clock speed, voltage, temperature, power consumption, etc.), workload characteristics (e.g., gaming, video processing, etc.), and other relevant data for the active application 118. This input 203 is used to establish a baseline for subsequent parameter adjustments. At block 904, the IOC 130 initializes the baseline parameter values based on the current configuration, using these initial values as the starting point for optimization.

At block 906, the IOC 130 selects a parameter for initial tuning based on its expected impact on the defined performance goals, such as increasing FPS or reducing power consumption. This initial selection, in at least some implementations, is guided by a multi-arm bandit algorithm (e.g., EQ 5) that prioritizes parameters that have the highest potential for improving performance. At block 908, the IOC 130 dynamically adjusts the selected parameter(s) using an RL model, iteratively modifying the value of the parameter while observing the resulting impact on the target performance metrics.

At block 910, the IOC 130 evaluates the performance impact of the applied changes to determine if the adjustment has met the target metric (e.g., increasing FPS). This evaluation compares the current performance against the baseline to measure the effectiveness of the change. At block 912, the IOC 130 checks for instability or suboptimal performance by monitoring for system crashes, performance drops, or other adverse conditions that may indicate that the current configuration of tuning system parameter values is not optimal. If instability is detected, the method proceeds to block 914.

At block 914, the IOC 130 rolls back to the previous stable configuration if instability or suboptimal performance is detected, restoring the system parameters to the last set of values 616 that ensured stable operation. If the system is stable (e.g., no unstable conditions or instability events detected), the method proceeds to block 916. At block 916, the RL model performs a Q-learning update to refine its understanding of the parameter's impact based on the observed performance and stability outcomes, adjusting its internal model to improve future tuning decisions. At block 918, the IOC 130 terminates further tuning if the target performance metric has been met or maintained after a threshold number of iterations has been performed or after a constant dip in the target metric was observed for a threshold number of iterations, and generates an optimization profile 222 that includes the current values/settings 620 at which the early stop was performed. If a rollback was required, the optimization profile 222 includes the stable (reverted) values/settings 616 of a previous iteration instead. This profile 222 is stored for future use to prevent the system from entering suboptimal states again.

At block 920, the IOC 130 uses the optimizer 314 to dynamically manage the application of the final optimization profile based on real-time context, such as varying workload conditions or user-defined performance goals. The optimizer 314 continuously monitors real-time system conditions and selectively applies the final tuning profile to ensure that the system maintains optimal performance. For example, if the initial profile suggests a higher resource allocation based on predicted rendering load, the optimizer 314 monitors the active application and reduces the parameters dynamically when transitioning to less demanding scenarios. Conversely, the optimizer 314 ramps up parameters when entering high-action sequences, ensuring smooth and responsive gameplay while maintaining system stability and efficiency.

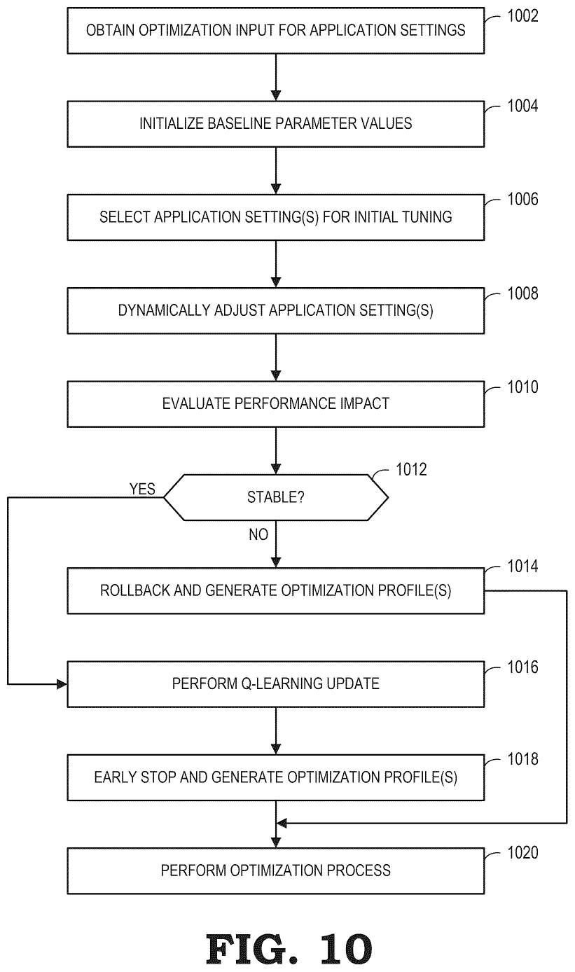

FIG. 10 illustrates a flow diagram of a method 1000 for dynamically adjusting application-specific settings in the application setting optimization mode of the IOC 130. The processes described below with respect to method 1000 have been described in greater detail with reference to FIG. 1 to FIG. 4 and FIG. 7 above. For purposes of description, the method 1000 is described with respect to an example implementation at the processing device 100 of FIG. 1, but it will be appreciated that, in other implementations, the method 1000 is implemented at processing systems having different configurations. Also, the method 1000 is not limited to the sequence of operations shown in FIG. 10, as at least some of the operations can be performed in parallel or in a different sequence. Moreover, in at least some implementations, the method 1000 can include one or more different operations than those shown in FIG. 10.

At block 1002, the IOC 130 collects optimization inputs 203, including application settings (e.g., resolution, texture quality, anti-aliasing, etc.), real-time system data (e.g., GPU utilization, temperature, power consumption, etc.), and one or more user-defined goals (e.g., target FPS, target visual quality preferences, etc.). This input 203 is used to establish a baseline for subsequent adjustments and represents the starting point for the optimization process. At block 1004, the IOC 130 initializes the baseline application settings using the current configuration to define the starting state for tuning operations.

At block 1006, the IOC 130 selects one or more application-specific settings for initial tuning based on their expected impact on user-defined performance targets, such as achieving high FPS for competitive gaming or maintaining high visual fidelity for immersive experiences. In at least some implementations, the IOC 130 prioritizes settings using a multi-arm bandit algorithm (e.g., EQ 5), to explore settings that are expected to have the most significant impact. At block 1008, the IOC 130 dynamically adjusts the selected application settings using an RL model. This model incrementally modifies values (e.g., lowering resolution or adjusting anti-aliasing settings) and tracks the effect on one or more performance metrics, such as FPS, latency, or power efficiency.

At block 1010, the IOC 130 evaluates the performance impact of each adjustment to determine if the changes meet the user-defined target metric. This evaluation compares the current performance against the initial baseline, measuring the effectiveness of the adjustment. At block 1012, the IOC 130 checks for instability or suboptimal performance conditions, such as FPS drops, input lag, or visual artifacts, which may indicate that the current configuration is unsuitable. If instability (e.g., an absence of instability events) is detected, the method proceeds to block 1014. At block 1014, the IOC 130 rolls back to the previous stable application values/settings 720 if instability or suboptimal performance is detected, restoring the system to a known good state. This rollback mechanism ensures that the processing device 100 maintains stability and user experience consistency. If stable conditions (no instability) are detected, the method proceeds to block 1016. At block 1016, the RL model performs a Q-learning update, refining its internal model of the impact of each parameter adjustment based on the observed feedback. The update is used to improve future decisions and adapt the tuning strategy for the specific application context.

At block 1018, the IOC 130 determines whether the tuning process should be terminated based on achieving the target performance goals or if further iterations are needed. If the target metric has been reached (e.g., stable high FPS, visual quality, etc.) or maintained after a threshold number of iterations or after a constant dip in the target metric was observed for a threshold number of iterations, the IOC 130 terminates tuning and generates an optimization profile 222 that includes the current stable settings 722. If a rollback was performed, the profile 222 includes the reverted values/settings 720 to prevent re-entry into suboptimal states. This profile 222 is then stored for future use.

At block 1020, the IOC 130 dynamically applies the final optimization profile 222 using the optimizer 314 and continuously manages the application-specific settings based on real-time operational context. For example, if the application transitions to a less demanding scenario, such as a menu screen or cutscene, the optimizer 314 reduces resource-intensive settings (e.g., lowering resolution or disabling anti-aliasing) to save power. Conversely, if the game transitions to a high-action scenario, the optimizer 314 re-applies the optimal settings to maintain smooth and responsive gameplay. This real-time adjustment ensures that the application operates under optimal settings while maintaining the balance between performance, visual quality, and system stability.

One or more of the elements described above is circuitry designed and configured to perform the corresponding operations described above. Such circuitry, in at least some implementations, is any one of, or a combination of, a hardcoded circuit (e.g., a corresponding portion of an application-specific integrated circuit (ASIC) or a set of logic gates, storage elements, and other components selected and arranged to execute the ascribed operations), a programmable circuit (e.g., a corresponding portion of a field programmable gate array (FPGA) or programmable logic device (PLD)), or one or more processors executing software instructions that cause the one or more processors to implement the ascribed actions. In some implementations, the circuitry for a particular element is selected, arranged, and configured by one or more computer-implemented design tools. For example, in some implementations, the sequence of operations for a particular element is defined in a specified computer language, such as a register transfer language, and a computer-implemented design tool selects, configures, and arranges the circuitry based on the defined sequence of operations.

Within this disclosure, in some cases, different entities (which are variously referred to as “components”, “units”, “devices”, “circuitry”, etc.) are described or claimed as “configured” to perform one or more tasks or operations. This formulation of [entity] configured to [perform one or more tasks] is used herein to refer to structure (i.e., something physical, such as electronic circuitry). More specifically, this formulation is used to indicate that this physical structure is arranged to perform the one or more tasks during operation. A structure can be said to be “configured to” perform some task even if the structure is not currently being operated. A “memory device configured to store data” is intended to cover, for example, an integrated circuit that has circuitry that stores data during operation, even if the integrated circuit in question is not currently being used (e.g., a power supply is not connected to it). Thus, an entity described or recited as “configured to” perform some task refers to something physical, such as a device, circuitry, memory storing program instructions executable to implement the task, etc. This phrase is not used herein to refer to something intangible. Further, the term “configured to” is not intended to mean “configurable to”. An unprogrammed field programmable gate array, for example, would not be considered to be “configured to” perform some specific function, although it could be “configurable to” perform that function after programming. Additionally, reciting in the appended claims that a structure is “configured to” perform one or more tasks is expressly intended not to be interpreted as having means-plus-function elements.

In some implementations, certain aspects of the techniques described above may be implemented by one or more processors of a processing system executing software. The software includes one or more sets of executable instructions stored or otherwise tangibly embodied on a non-transitory computer-readable storage medium. The software can include the instructions and certain data that, when executed by the one or more processors, manipulate the one or more processors to perform one or more aspects of the techniques described above. The non-transitory computer-readable storage medium can include, for example, a magnetic or optical disk storage device, solid-state storage devices such as Flash memory, a cache, random access memory (RAM) or other non-volatile memory device or devices, and the like. The executable instructions stored on the non-transitory computer-readable storage medium may be in source code, assembly language code, object code, or another instruction format that is interpreted or otherwise executable by one or more processors.

Note that not all of the activities or elements described above in the general description are required, that a portion of a specific activity or device may not be required, and that one or more further activities may be performed, or elements included, in addition to those described. Still further, the order in which activities are listed is not necessarily the order in which they are performed. Also, the concepts have been described with reference to specific implementations. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific implementations. However, the benefits, advantages, solutions to problems, and any feature(s) that may cause any benefit, advantage, or solution to occur or become more pronounced are not to be construed as a critical, required, or essential feature of any or all the claims. Moreover, the particular implementations disclosed above are illustrative only, as the disclosed subject matter may be modified and practiced in different but equivalent manners apparent to those skilled in the art having the benefit of the teachings herein. No limitations are intended to the details of construction or design herein shown, other than as described in the claims below. It is, therefore, evident that the particular implementations disclosed above may be altered or modified, and all such variations are considered within the scope of the disclosed subject matter. Accordingly, the protection sought herein is as set forth in the claims below.

What is claimed is:

1. A method, at a processing system, comprising:
measuring, by the processing system, at least one performance metric associated with an application;
responsive to a first input comprising a first encoded representation of at least a first hardware component of the processing system, a second input comprising a second encoded representation of the application, and a third input comprising a target change in the at least one performance metric associated with the application, generating, by an inference engine using one or more trained models, an output comprising at least one recommended hardware component upgrade for the processing system; and
presenting the at least one recommended hardware component upgrade to a user on a display coupled to the processing system.

2. The method of claim 1, wherein generating the output further comprises:
based on the first input, the second input, and the third input, selecting, by the inference engine, a hardware component from a plurality of hardware components of the same type that achieves the target change in the at least one performance metric; and
outputting, by the inference engine, the selected hardware component as the at least one recommended hardware component upgrade.

3. The method of claim 1, wherein the target change in the at least one performance metric is at least one of:
an increase in frames per second;
a reduction in input latency to the application;
an increase is power efficiency of at least one of a central processing unit or a graphics processing unit of the processing system; or
a decrease in thermal output of at least one of the central processing unit or the graphics processing unit.

4. The method of claim 1, further comprising:
generating the first encoded representation by performing a first feature extraction operation on a first set of attributes associated with the at least first hardware component, wherein the first encoded representation is a structured, numerical representation of the at least first hardware component; and
generating the second encoded representation by performing a second feature extraction operation on a second set of attributes associated with the application, wherein the second encoded representation is a structured, numerical representation of the application.

5. The method of claim 4, wherein generating the first encoded representation further comprises:
responsive to the first feature extraction operation, normalizing and formatting the first set of attributes into a first structured numerical representation, and
wherein generating the first encoded representation further comprises:
responsive to the second feature extraction operation, normalizing and formatting the second set of attributes into a second structured numerical representation.

6. The method of claim 1, further comprising:
training each of the one or more trained models on a dataset comprising a plurality of encoded system configurations and resulting corresponding performance metric values.

7. The method of claim 6, wherein each encoded system configuration in the plurality of encoded system configurations comprises at least one encoding of a central processing unit, a graphics processing unit, a display, and an application, and is associated with a performance metric value indicative of an operational outcome for that encoded system configuration.

8. The method of claim 1, wherein generating the output further comprises:
selecting the at least one recommended hardware component based on a prediction from the one or more trained models that indicates the at least one recommended hardware component will achieve the target change in the at least one performance metric.

9. The method of claim 1, wherein the one or more trained models comprise an ensemble of trained models including a random forest model, a k-nearest neighbor model, a lasso model, and a deep neural network model.

10. A processing system comprising:
a plurality of hardware components; and
an intelligent optimization component comprising at least one inference engine configured to:
measure at least one performance metric associated with an application;
responsive to a first input comprising a first encoded representation of at least a first hardware component of the plurality of hardware components, a second input comprising a second encoded representation of the application, and a third input comprising a target change in the at least one performance metric associated with the application, generate an output comprising at least one recommended hardware component upgrade for the processing system; and
present the at least one recommended hardware component upgrade to a user on a display coupled to the processing system.

11. The processing system of claim 10, wherein the at least one inference engine is configured to generate the output by:
based on the first input, the second input, and the third input, selecting a hardware component from a plurality of hardware components of the same type that achieves the target change in the at least one performance metric; and
outputting the selected hardware component as the at least one recommended hardware component upgrade.

12. The processing system of claim 10, wherein the target change in the at least one performance metric is at least one of:
an increase in frames per second;
a reduction in input latency to the application;
an increase is power efficiency of at least one of a central processing unit or a graphics processing unit of the processing system; or
a decrease in thermal output of at least one of the central processing unit or the graphics processing unit.

13. The processing system of claim 10, wherein the intelligent optimization component further comprises an encoder configured to:
generate the first encoded representation by performing a first feature extraction operation on a first set of attributes associated with the at least first hardware component, wherein the first encoded representation is a structured, numerical representation of the at least first hardware component; and
generate the second encoded representation by performing a second feature extraction operation on a second set of attributes associated with the application, wherein the second encoded representation is a structured, numerical representation of the application.

14. The processing system of claim 13, wherein the encoder is further configured to generate the first encoded representation by:
responsive to the first feature extraction operation, normalizing and formatting the first set of attributes into a first structured numerical representation, and
wherein the encoder is further configured to generate the second encoded representation by:
responsive to the second feature extraction operation, normalizing and formatting the second set of attributes into a second structured numerical representation.

15. The processing system of claim 10, wherein the inference engine is configured to generate the output by:
analyzing, using one or more trained models, the first encoded representation, the second encoded representation, and the target change in the at least one performance metric associated with the application to predict at least one recommended hardware component for upgrading the processing system, wherein each of the one or more trained models is trained on a dataset comprising a plurality of encoded system configurations and resulting corresponding performance metric values.

16. The processing system of claim 15, wherein each encoded system configuration in the plurality of encoded system configurations comprises at least one encoding of a central processing unit, a graphics processing unit, a display, and an application, and is associated with a performance metric value indicative of an operational outcome for that encoded system configuration.

17. The processing system of claim 15, wherein inference engine is configured to generate the output by:
selecting the at least one recommended hardware component based on a prediction from the one or more trained models that indicates the at least one recommended hardware component will achieve the target change in the at least one performance metric.

18. The processing system of claim 15, wherein the one or more trained models comprise an ensemble of trained models including, a random forest model, a k-nearest neighbor model, a lasso model, and a deep neural network model.

19. A method, at a processing system, comprising:
obtaining a plurality of training data instances, each training data instance representing a different encoded system configuration comprising a first encoded representation of at least one hardware component, a second encoded representation of an application, and a performance metric value indicative of an operational outcome for that encoded system configuration;
training an ensemble model using the plurality of training data instances, the ensemble model comprising a plurality of machine learning models;
updating, during the training, parameters of each machine learning model of the ensemble model based on a prediction error determined for the corresponding machine learning model until a convergence criterion is satisfied; and
responsive to satisfying the convergence criterion, outputting the trained ensemble model, the trained ensemble model configured to generate a recommended hardware upgrade for the processing system based on encoded representations of a system configuration and one or more applications.

20. The method of claim 19, further comprising:
responsive to a first input comprising an encoded representation at least one hardware component of the processing system and a second input comprising an encoded representation of an application, generating, by an inference engine implementing the trained ensemble model, an output comprising at least one recommended hardware component upgrade for the processing system; and
presenting the at least one recommended hardware component upgrade to a user on a display coupled to the processing system.
